(19) United States
(12) Patent Application Publication
(10) Pub. No.: US 2006/0137712 A1
(43) Pub. Date: Jun. 29, 2006

(54) Cleaning apparatus and method for electronic device

(76) Inventors: Yukihisa Wada, Kyoto (JP); Masayuki Watanabe, Toyama (JP)

Correspondence Address: MCDERMOTT WILL & EMERY LLP, 600 13TH STREET, N.W., WASHINGTON, DC, 20005-3096, US

(21) Appl. No.: 11/260,568

(22) Filed: Oct. 28, 2005

(30) Foreign Application Priority Data
Dec. 27, 2004 (JP) 2004-377165

(51) Int. Cl. C23G 1/00; B08B 7/04; B08B 3/00; C03C 15/00; B08B 3/12; C23F 1/00; H01L 21/306

(52) U.S. Cl. 134/2; 134/10; 134/184; 134/58 R; 216/84; 156/345.18; 156/345.24

(57) ABSTRACT

A method for cleaning electronic devices including the step of cleaning a target substrate placed in a cleaning chamber by etching using a cleaning solution which is circulated for reuse in a cleaning solution circulation path including at least the cleaning chamber and a cleaning solution circulation line, the method further including the steps of: (a) determining etch time based on data concerning variations in amount of a target film on the target substrate etched by the cleaning solution, the variations depending on time elapsed since the cleaning solution was fed into the cleaning solution circulation path; (b) etching the target substrate in the cleaning chamber using the cleaning solution for the determined etch time; and (c) rinsing the target substrate with water.

### CROSS-REFERENCE TO RELATED APPLICATION

This non-provisional application claims priority under 35 U.S.C. §119(a) of Japanese Patent Application No. 2004-377165 filed in Japan on Dec. 27, 2004, the entire contents of which are hereby incorporated by reference.

### BACKGROUND OF THE INVENTION

1. Field of the Invention

The present invention relates to a cleaning apparatus for electronic devices and a method for cleaning the electronic devices.

2. Description of Related Art

In recent years, electronic devices have been rapidly improved in operating speed and packaging density. Aiming at higher operating speed and higher packaging density, miniaturization of the electronic devices has been in progress. Therefore, in the cleaning step performed after every manufacturing step, it has been required to reduce variations in amount of a target film etched by a cleaning solution.

In a cleaning apparatus which circulates the cleaning solution for reuse, some of the components of the cleaning solution having a low vapor pressure evaporate with time shortly after the preparation of the cleaning solution. That is, the composition of the cleaning solution varies with time shortly after the preparation of the cleaning solution and the etch rate of the target film varies. As a result, the electronic devices are not manufactured with stability, thereby reducing manufacturing yield of the electronic devices.

As a solution to this problem, the following first and second conventional examples have been proposed.

First, an explanation is given of the first conventional example relating to a method for reducing variations in etch amount of the target film by suitably controlling when to replace the cleaning solution.

Hereinafter, with reference to FIGS. 24 and 25, an explanation of the structure of a batch-type cleaning apparatus according to the first conventional example is provided.

FIG. 24 shows the structure of the batch-type cleaning apparatus for electronic devices according to the first conventional example.

FIG. 25 is a sectional view illustrating the specific structure of the batch-type cleaning apparatus for electronic devices according to the first conventional example.

As shown in FIG. 24, the batch-type cleaning apparatus 100 of the first conventional example includes a circulation bath 101, a rinsing bath 102 and a dry bath 103.

In the circulation bath 101, as shown in FIG. 25, a cleaning solution is circulated in a circulation part and a target substrate is cleaned with a cleaning solution in a cleaning part. Specifically, the circulation part includes a circulation line 200, a circulation pump 201, an electronic thermoregulator 202 and a filter 203. The cleaning part includes an inner treatment bath 204, an outer treatment bath 205, a bath cover 206 and a cleaning solution nozzle 207.

Hereinafter, referring to FIG. 26, an explanation is given of a correlation between lifetime and etch amount found when the batch-type cleaning apparatus of the first conventional example is used.

The lifetime mentioned herein is time elapsed since the cleaning solution was fed into the circulation line 200.

FIG. 26 is a graph illustrating the correlation between lifetime and etch amount found when the batch-type cleaning apparatus of the first conventional example is used.

In the batch-type cleaning apparatus, a buffered hydrofluoric acid solution (containing 0.10% HF and 39.0% NH₄F) is fed into the circulation line 200 as the cleaning solution and the temperature of the buffered hydrofluoric acid solution (hereinafter abbreviated as BHF solution) is controlled at 21° C. by the electronic thermoregulator 202 provided on the circulation line 200.

With the temperature of the BHF solution kept at a certain temperature (e.g., 21° C.) by the electronic thermoregulator 202, a target substrate is immersed in the BHF solution contained in the inner treatment bath 204 for certain etch time (e.g., 3 minutes) to etch a film (thermal oxide film) on the target substrate.

Then, by measuring the etch amounts of the thermal oxide film corresponding to different lifetimes, the correlation between lifetime and etch amount is evaluated.

Under the above-described conditions, the amounts of the thermal oxide film etched by the BHF solution are measured at different lifetimes (0, 12, 24 and 48 hours). Then, the etch amounts of the thermal oxide film corresponding to the lifetimes are plotted as shown in FIG. 26 to evaluate the correlation between lifetime and etch amount.

The results shown in FIG. 26 indicate that the etch amount of the thermal oxide film increases at a certain rate with an increase in lifetime.

Specifically, 4.0 nm of the thermal oxide film is etched by the BHF solution which has just fed into the circulation line 200, i.e., when the lifetime is 0 hour. On the other hand, 5.6 nm of the thermal oxide film is etched by the BHF solution after the lifetime of 24 hours has passed. Thus, the amount etched by the BHF solution which has spent 24-hour lifetime is 40% larger than the amount etched by the BHF solution which has spent 0-hour lifetime.

If the allowable range of variations in etch amount of the thermal oxide film is, for example, ±20%, i.e., 4.0±0.8 (nm), the batch-type cleaning apparatus of the first conventional example requires the cleaning solution flowing through the circulation line 200 to be replaced every 12 hours so as not to deviate from the allowable range as shown in FIG. 26.

Thus, in using the batch-type cleaning apparatus of the first comparative example, the cleaning solution is replaced every predetermined time to reduce the variations in etch amount of the target film.

Then, referring to FIG. 27, an explanation of a single-wafer cleaning apparatus as another cleaning apparatus according to the first conventional example is provided.

FIG. 27 is a view illustrating the structure of a single-wafer cleaning apparatus for electronic devices according to the first comparative example.

The single-wafer cleaning apparatus of the first comparative example includes a circulation part, a cleaning part and a rinsing part as shown in FIG. 27.

The circulation part includes a circulation line 300, a circulation pump 301, a circulation tank 302, an electronic thermoregulator 303 and a filter 304 and a cleaning solution is circulated therein. The cleaning part includes a cleaning chamber 305, a cup 306, a cleaning solution nozzle 307, a HEPA 308 and a holder 309 and is adapted to clean a target substrate. The rinsing part includes a rinsing nozzle 310 to rinse the target substrate with water.

Hereinafter, with reference to FIG. 28, an explanation is given of correlation between cumulative time and etch amount found when the single-wafer cleaning apparatus of the first comparative example is used.

The cumulative time mentioned herein signifies the sum of durations spent for etching a target film on the target substrate since the cleaning solution was fed into the circulation line 300.

FIG. 28 is a graph illustrating the correlation between cumulative time and etch amount found when the single-wafer cleaning apparatus of the first comparative example is used.

In the single-wafer cleaning apparatus of the first comparative example, a polymer solution (containing 0.5% NH₄F, 45% organic solvent and 54.5% water) is fed into the circulation line 300 as the cleaning solution. The temperature of the polymer solution is controlled at 25° C. by the electronic thermoregulator 303 provided on the circulation line 300.

With the polymer solution kept at a certain etching temperature (e.g., 25° C.) by the electronic thermoregulator 303, the polymer solution is fed from the cleaning solution nozzle 307 onto a target substrate supported on the holder 309 for certain etch time (e.g., 3 minutes), thereby etching a target film (plasma TEOS film) on the target substrate. At this time, the target substrate is being rotated at predetermined revolutions.

By measuring the etch amounts of the plasma TEOS film corresponding to different cumulative times, the correlation between cumulative time and etch amount is evaluated.

Under the above-described conditions, the amounts of the plasma TEOS film corresponding to different cumulative times (0, 300, 600 and 900 minutes) are measured. Then, the etch amounts corresponding to the different cumulative times are plotted as shown in FIG. 28 to evaluate the correlation between cumulative time and etch amount.

The results shown in FIG. 28 indicate that the etch amount of the plasma TEOS film varies at a certain rate with an increase in cumulative time.

Specifically, 0.3 nm of the plasma TEOS film is etched when the cumulative time of the polymer solution is 0 minute. On the other hand, 0.6 nm of the plasma TEOS film is etched when the cumulative time of the polymer solution is 900 minutes. Thus, the amount etched by the polymer solution which has spent 900-minute cumulative time is about 100% larger than the amount etched by the polymer solution which has spent 0-minute cumulative time.

If the allowable range of the variations in etch amount of the plasma TEOS film is ±50%, i.e., 0.30±0.15 (nm), the single-wafer cleaning apparatus of the first conventional example requires the cleaning solution flowing through the circulation line 300 to be replaced every time after 150 wafers were treated (450 minutes of cumulative time) so as not to deviate from the allowable range of the variations as shown in FIG. 28.

Thus, with the single-wafer cleaning apparatus of the first comparative example, the cleaning solution is replaced every predetermined time to reduce the variations in etch amount of the target film.

As described above, the cleaning apparatuses according to the first comparative example reduce the variations in etch amount of the target film by replacing the cleaning solution every lapse of a predetermined time after the cleaning solution was fed into the circulation line.

Then, an explanation is given of a second conventional example relating to a method for reducing the variations in etch amount of the target film including the step of adding a component of the cleaning solution whose amount varies with time (for example, see Japanese Unexamined Patent Publication No. 2002-143791).

Hereinafter, a cleaning apparatus for electronic devices according to the second conventional example is described with reference to FIGS. 29 and 30.

FIG. 29 is a schematic view illustrating the structure of the cleaning apparatus of the second conventional example.

FIG. 30 is a graph illustrating a relationship between elapsed time and etch rate and a relationship between elapsed time and hydrofluoric acid (HF) concentration in the cleaning solution which are found when the cleaning apparatus of the second conventional example is used.

As shown in FIG. 29, the cleaning apparatus of the second conventional example includes a cleaning bath 400, a circulation pump 401, a reservoir 402 and a control unit 403.

In this cleaning apparatus, a solution made of ammonium fluoride and hydrogen fluoride is used as the cleaning solution.

The cleaning bath 400 is filled with the cleaning solution made of ammonium fluoride and hydrogen fluoride and a target substrate is immersed in the cleaning solution to etch a target film formed thereon. An overflow of the cleaning solution from the cleaning bath 400 is returned to the cleaning bath 400 through the circulation pump 401.

The reservoir 402 contains ammonia water to be added to the cleaning bath 400 at a command of the control unit 403. By adding the ammonia water, the composition of the cleaning solution in the cleaning bath 400 is kept uniform at all times.

In FIG. 30, line La schematically indicates change in etch rate of the target film and change in HF concentration in the cleaning solution upon addition of the ammonia water to the cleaning bath 400 from the reservoir 402 every predetermined time.

On the other hand, straight line Lb schematically indicates change in etch rate of the target film and change in HF concentration in the cleaning solution when the ammonia water in the reservoir 402 is not added to the cleaning bath 400.

As shown in FIG. 30, the straight line Lb indicates that the etch rate of the target film increases at a certain rate. The line La shows that the etch rate of the target film once increases at the same rate as that indicated by the straight line Lb, but upon addition of the ammonia water to the cleaning bath 400 from the reservoir 402, the etch rate returns to the initial level same as that when a fresh cleaning solution has just introduced into the cleaning bath 400. After that, as indicated by the line La, the etch rate of the target film increases again at the same rate as that indicated by the straight line Lb. Then, upon another addition of the ammonia water into the cleaning bath 400, the etch rate of the target film returns again to the initial level same as that when a fresh cleaning solution has just introduced into the cleaning bath 400.

In this way, the ammonia water in the reservoir 402 is added to the cleaning bath 400 every predetermined time at a command of the control unit 403, thereby keeping the composition of the cleaning solution in the cleaning bath 400 uniform at all times. Therefore, variations in HF concentration in the cleaning solution are reduced, thereby reducing variations in etch rate of the target film.

However, in recent cleaning apparatuses for electronic devices, a larger quantity of the cleaning solution is required as the size of the target substrate increases. Further, as to the cleaning apparatuses of the first conventional example, the variations in etch amount of the target film must be reduced as possible from the viewpoint of the miniaturization of the electronic devices, and therefore the cleaning solution must be replaced more frequently. This brings about an increase in quantity of the cleaning solution used. In addition, the operating rate of the cleaning apparatus decreases and the cost of manufacturing the electronic devices increases.

On the other hand, when a multicomponent solution such as a polymer solution is used as the cleaning solution in the cleaning apparatus of the second conventional example, one of the components of the polymer solution evaporates selectively. Since it is impossible to supplement only the evaporated component every predetermined time, unwanted components are also supplemented to the cleaning solution. Even if the cleaning solution is supplemented, it is still difficult to keep the composition of the cleaning solution uniform. Thus, it is difficult to maintain the etch rate uniform.

### SUMMARY OF THE INVENTION

In view of the problems described above, an object of the present invention is to provide an apparatus and a method for cleaning electronic devices which make it possible to reduce the frequency of replacement of the cleaning solution, thereby reducing the quantity of the cleaning solution used, improving the operating rate of the cleaning apparatus and maintaining the etch amount uniform.

In order to achieve the above-described object, according to an aspect of the present invention, provided is a method for cleaning electronic devices including the step of etching a target substrate placed in a cleaning chamber using a cleaning solution which is circulated for reuse in a cleaning solution circulation path including at least the cleaning chamber and a cleaning solution circulation line, the method further including the steps of: (a) determining etch time based on data concerning variations in amount of a target film on the target substrate etched by the cleaning solution, the variations depending on time elapsed since the cleaning solution was fed into the cleaning solution circulation path; (b) etching the target substrate in the cleaning chamber using the cleaning solution for the determined etch time; and (c) rinsing the target substrate with water.

By the method for cleaning the electronic devices according to the first aspect of present invention, the target film is etched for certain etch time which is determined based on variations in amount of the target film etched by the cleaning solution. Therefore, the target film is etched for suitable etch time corresponding to the elapsed time.

Therefore, even if the etch rate of the target film varies with a change in elapsed time, the target film is etched under the suitable etching condition corresponding to the elapsed time, i.e., the etch amount of the target film is prevented from varying depending on the change in elapsed time. As a result, the etch amount of the target film is surely controlled to a desired level corresponding to the elapsed time. Thus, the etch amount is kept uniform regardless of the elapsed time.

Further, unlike the conventional examples, there is no need of replacing the cleaning solution flowing through the cleaning solution circulation path every time after a certain period has elapsed since the cleaning solution was fed into the cleaning solution circulation path. That is, the cleaning solution is used for prolonged time, and therefore replacement of the cleaning solution is carried out less frequently. As a result, the quantity of the cleaning solution used is reduced and the operating rate of the cleaning apparatus improves, thereby leading to reduction in cost of manufacturing electronic devices.

As to the method for cleaning electronic devices according to the first aspect of the present invention, the etch time is preferably determined based on data concerning variations in amount of the target film etched in the step (c) by the remainder of the cleaning solution used in the step (b).

By so doing, the etch time is determined based on not only the variations in amount of the target film etched by the cleaning solution but also the variations in amount of the target film etched by the remainder of the cleaning solution after the preceding etching step. Therefore, the target film is etched for suitable etch time which is determined with higher accuracy.

Therefore, even if the etch rate of the target film varies with a change in elapsed time, the target film is etched under the suitable etching condition corresponding to the elapsed time, i.e., the etch amount of the target film is prevented from varying depending on the change in elapsed time. As a result, the etch amount of the target film is surely controlled to a desired level corresponding to the elapsed time. Thus, the etch amount is kept uniform regardless of the elapsed time.

Further, unlike the conventional examples, there is no need of replacing the cleaning solution flowing through the cleaning solution circulation path every time after a certain period has elapsed since the cleaning solution was fed into the cleaning solution circulation path. Therefore, replacement of the cleaning solution is carried out less frequently. As a result, the quantity of the cleaning solution used is reduced and the operating rate of the cleaning apparatus improves, thereby leading to reduction in cost of manufacturing electronic devices.

As to the method for cleaning electronic devices according to the first aspect of the present invention, the etch time is preferably determined based on data concerning variations in etch amount of the target film that depend on time elapsed since the cleaning solution was fed into the cleaning solution circulation path until the cleaning solution is discharged from the cleaning solution circulation path.

By so doing, in the cleaning apparatus according to the first aspect of the present invention, the target film is etched for suitable etch time corresponding to time elapsed since the cleaning solution was fed into the cleaning solution circulation path (i.e., lifetime).

As to the method for cleaning electronic devices according to the first aspect of the present invention, the etch time is preferably determined by the formula [1]:
Etch time={Intended etch amount−[Additional etch amount (C)+Additional etch rate (D)×Lifetime]}/{Etch rate (A)+Increase coefficient (B)×Lifetime}

wherein

the lifetime indicates time elapsed since the cleaning solution was fed into the cleaning solution circulation path, the increase coefficient (B) is a value indicating the rate at which the etch rate of the target film increases with an increase in lifetime, the etch rate (A) is a value indicating the rate at which the amount of the target film etched in the step (b) by the cleaning solution which has just fed into the cleaning solution circulation path increases with an increase in etch time, the additional etch amount (C) is a value indicating the amount of the target film additionally etched in the step (c) by the remainder of the cleaning solution which has just fed into the cleaning solution circulation path and the additional etch rate (D) is a value indicating the rate at which the additional etch amount increases with an increase in lifetime.

By so doing, in the cleaning apparatus according to the first aspect of the present invention, etch time corresponding to the lifetime of the cleaning solution used is determined by using the formula [1] as a correction formula.

Specifically, the increase coefficient (B) of the formula [1] is obtained from a first average etch rate of the target film obtained when the cleaning solution has spent a first lifetime and a second average etch rate of the target film obtained when the cleaning solution has spent a second lifetime different from the first lifetime.

The etch rate (A) of the formula [1] is obtained from the ratio of variations in etch amount of the target film with respect to variations in etch time spent for etching the target film when a cleaning solution which has just fed into the cleaning solution circulation path is used.

The additional etch amount (C) and the additional etch rate (D) of the formula [1] are obtained in the following manner. First, a first etch amount of the target film etched for first etch time by the cleaning solution which has spent a third lifetime is obtained and a second etch amount of the target film etched for second etch time different from the first etch time by the cleaning solution which has spent the third lifetime is obtained. From these values, a first additional etch amount indicating the amount of the target film etched by the remainder of the cleaning solution which has spent the third lifetime is obtained. Then, a third etch amount of the target film etched for third etch time by the cleaning solution which has spent a fourth lifetime is obtained and a fourth etch amount of the target film etched for fourth etch time different from the third etch time by the cleaning solution which has spent the fourth lifetime is obtained. From these values, a second additional etch amount indicating the amount of the target film etched by the remainder of the cleaning solution which has spent the fourth lifetime is obtained. Then, from the first additional etch amount corresponding to the third lifetime and the second additional etch amount corresponding to the fourth lifetime, the additional etch amount (C) and the additional etch rate (D) are obtained.

By obtaining the increase coefficient (B), etch rate (A), additional etch amount (C) and additional etch rate (D) in this manner, a correction formula for the cleaning apparatus according to the first aspect of the present invention is obtained.

In the cleaning apparatus according to the first aspect of the present invention, the formula [1] is established as a correction formula and the etch time corresponding to the lifetime is determined based on the formula [1]. Accordingly, the target film is etched for suitable etch time corresponding to the lifetime.

As to the method for cleaning electronic devices according to the first aspect of the present invention, it is preferable that the cleaning chamber is adapted to a single-wafer cleaning apparatus and the etch time is determined based on data concerning variations in etch amount of the target film that depend on cumulative time spent for etching the target substrate since the cleaning solution was fed into the cleaning solution circulation path.

By so doing, when the single-wafer cleaning apparatus is used as the cleaning apparatus according to the first aspect of the present invention, the target film is etched for a period of time obtained by adding durations which have been spent for etching the target film since the cleaning solution was fed into the cleaning solution circulation path (i.e., cumulative time).

As to the method for cleaning electronic devices according to the first aspect of the present invention, the etch time is determined by the formula [2]:
Etch time={Intended etch amount−[Additional etch amount (G)+Additional etch rate (H)×Cumulative time]}/{Etch rate (E)+Increase coefficient (F)×Cumulative time}

wherein the cumulative time is a value indicating the sum of durations spent for etching the target substrate since the cleaning solution was fed into the cleaning solution circulation path, the increase coefficient (F) is a value indicating the rate at which the etch rate of the target film increases with an increase in cumulative time, the etch rate (E) is a value indicating the rate at which the amount of the target film etched in the step (b) by the cleaning solution which has just fed into the cleaning solution circulation path increases with an increase in etch time, the additional etch amount (G) is a value indicating the amount of the target film additionally etched in the step (c) by the remainder of the cleaning solution which has just fed into the cleaning solution circulation path and the additional etch rate (H) is a value indicating a rate at which the additional etch amount increases with an increase in cumulative time.

If the formula [2] is used as a correction formula when the single-wafer cleaning apparatus is used as the cleaning solution according to the first aspect of the present invention, suitable etch time corresponding to the cumulative time is determined.

Specifically, the increase coefficient (F) of the formula [2] is obtained from a first average etch rate of the target film obtained when the cleaning solution has spent first cumulative time and a second average etch rate of the target film obtained when the cleaning solution has spent second cumulative time different from the first cumulative time.

The etch rate (E) of the formula [2] is obtained from the ratio of variations in etch amount of the target film with respect to variations in etch time spent for etching the target film when a cleaning solution which has just fed into the cleaning solution circulation path is used.

The additional etch amount (G) and the additional etch rate (H) of the formula [2] are obtained in the following manner. First, a first etch amount of the target film etched for first etch time by the cleaning solution which has spent third cumulative time is obtained and a second etch amount of the target film etched for second etch time different from the first etch time by the cleaning solution which has spent the third cumulative time is obtained. From these values, a first additional etch amount indicating the amount of the target film etched by the remainder of the cleaning solution which has spent the third cumulative time is obtained. Then, a third etch amount of the target film etched for third etch time by the cleaning solution which has spent fourth cumulative time is obtained and a fourth etch amount of the target film etched for fourth etch time different from the third etch time by the cleaning solution which has spent the fourth cumulative time is obtained. From these values, a second additional etch amount indicating the amount of the target film etched by the remainder of the cleaning solution which has spent the fourth cumulative time is obtained. Then, from the first additional etch amount corresponding to the third cumulative time and the second additional etch amount corresponding to the fourth cumulative time, the additional etch amount (G) and the additional etch rate (H) are obtained.

By obtaining the increase coefficient (F), etch rate (E), additional etch amount (G) and additional etch rate (H) in this manner, a correction formula for the single-wafer cleaning apparatus according to the first aspect of the present invention is obtained.

In the cleaning apparatus according to the first aspect of the present invention, the formula [2] is established as a correction formula and the etch time corresponding to the cumulative time is determined based on the formula [2]. Accordingly, the target film is etched for suitable etch time corresponding to the cumulative time.

According to the second aspect of the present invention, provided is a method for cleaning electronic devices including the step of etching a target substrate placed in a cleaning chamber using a cleaning solution which is circulated for reuse in a cleaning solution circulation path including at least the cleaning chamber and a cleaning solution circulation line, the method further including the steps of: (d) determining etching temperature based on data concerning variations in amount of a target film on the target substrate etched by the cleaning solution, the variations depending on time elapsed since the cleaning solution was fed into the cleaning solution circulation path; (e) etching the target substrate in the cleaning chamber using the cleaning solution controlled at the determined etching temperature; and (f) rinsing the target substrate with water.

By the cleaning method according to the second aspect of the present invention, etching temperature is determined based on variations in amount of the target film etched by the cleaning solution and variations in amount of the target film etched by the remainder of the cleaning solution after the preceding etching step. Therefore, the target film is etched at a suitable etching temperature corresponding to the elapsed time.

As a result, the etch rate of the target film will not vary with a change in elapsed time, whereby the target film is etched under the suitable etching condition corresponding to the elapsed time. This surely prevents the etch amount of the target film from varying depending on the change in elapsed time. As a result, the etch amount of the target film is surely controlled to a desired level corresponding to the elapsed time. Thus, the etch amount is kept uniform regardless of the elapsed time.

Further, unlike the conventional examples, there is no need of replacing the cleaning solution flowing through the cleaning solution circulation path every time after a certain period has elapsed since the cleaning solution was fed into the cleaning solution circulation path. Therefore, replacement of the cleaning solution is carried out less frequently. As a result, the quantity of the cleaning solution used is reduced and the operating rate of the cleaning apparatus improves, thereby leading to reduction in cost of manufacturing electronic devices.

As to the method for cleaning electronic devices according to the second aspect of the present invention, the etching temperature is preferably determined based on data concerning variations in etch amount of the target film that depend on time elapsed since the cleaning solution was fed into the cleaning solution circulation path until the cleaning solution is discharged from the cleaning solution circulation path.

By so doing, in the cleaning apparatus according to the second aspect of the present invention, the target film is etched at a suitable etching temperature corresponding to time elapsed since the cleaning solution was fed into the cleaning solution circulation path (i.e., lifetime).

As to the method for cleaning electronic devices according to the second aspect of the present invention, it is preferable that the cleaning chamber is adapted to a single-wafer cleaning apparatus and the etching temperature is determined based on data concerning variations in etch amount of the target film that depend on cumulative time spent for etching the target substrate since the cleaning solution was fed into the cleaning solution circulation path.

By so doing, when the single-wafer cleaning apparatus is used as the cleaning apparatus according to the second aspect of the present invention, the target film is etched at a suitable etching temperature corresponding to the sum of durations spent for etching the target film since the cleaning solution was fed into the cleaning solution circulation path (i.e., cumulative time).

As to the method for cleaning electronic devices according to the first or second aspect of the present invention, the cleaning solution preferably contains a fluorine compound.

An apparatus for cleaning electronic devices according to the first aspect of the present invention includes: a cleaning solution circulation path which circulates a cleaning solution therein for reuse and includes a cleaning solution circulation line which is provided with a temperature regulator mechanism for controlling the temperature of the cleaning solution and a cleaning chamber in which the target substrate is cleaned; and a control unit for measuring time elapsed since the cleaning solution was fed into the cleaning solution circulation path and determining etch time based on data concerning variations in amount of a target film on the target substrate etched by the cleaning solution, the variations depending on the elapsed time, wherein the target substrate is etched in the cleaning chamber using the cleaning solution for the etch time determined by the control unit.

The cleaning apparatus according to the first aspect of the present invention includes the control unit. The control unit determines etch time corresponding to the elapsed time based on variations in amount of the target film etched by the cleaning solution. Further, in the cleaning solution circulation path of the cleaning apparatus according to the first aspect of the present invention, the temperature of the cleaning solution is controlled by the temperature regulator mechanism.

Therefore, in the cleaning chamber of the cleaning apparatus according to the first aspect of the present invention, a temperature-controlled cleaning solution is used. Therefore, the target film is etched at a certain etching temperature for etch time corresponding to the elapsed time.

Therefore, even if the etch rate of the target film varies with a change in elapsed time, the target film is etched under the suitable etching condition corresponding to the elapsed time, i.e., the etch amount of the target film is prevented from varying depending on the change in elapsed time. As a result, the etch amount of the target film is surely controlled to a desired level corresponding to the elapsed time. Thus, the etch amount is kept uniform regardless of the elapsed time.

Further, unlike the conventional examples, there is no need of replacing the cleaning solution flowing through the cleaning solution circulation path every time after a certain period has elapsed since the cleaning solution was fed into the cleaning solution circulation path. Therefore, replacement of the cleaning solution is carried out less frequently. As a result, the quantity of the cleaning solution used is reduced and the operating rate of the cleaning apparatus improves, thereby leading to reduction in cost of manufacturing electronic devices.

As to the apparatus for cleaning electronic devices according to the first aspect of the present invention, it is preferable that the control unit selects a desired etch time from a plurality of previously set etch times depending on the determined etch time or changes a previously selected etch time to a desired etch time depending on the determined etch time.

By so doing, the target film is etched for suitable etch time determined by the control unit to correspond to the elapsed time.

As to the apparatus for cleaning electronic devices according to the first aspect of the present invention, the control unit preferably determines the etch time based on data concerning variations in amount of the target film etched by the remainder of the cleaning solution.

By so doing, suitable etch time corresponding to the elapsed time is determined based on not only variations in amount of the target film etched by the cleaning solution but also variations in amount of the target film etched by the remainder of the cleaning solution after the etching step.

As a result, in the cleaning chamber of the cleaning apparatus according to the first aspect of the present invention, a temperature-controlled cleaning solution is used. Therefore, the target film is etched at a certain etching temperature for suitable etch time determined with high accuracy.

Therefore, even if the etch rate of the target film varies with a change in elapsed time, the target film is etched under the suitable etching condition corresponding to the elapsed time, i.e., the etch amount of the target film is prevented from varying depending on the change in elapsed time. As a result, the etch amount of the target film is surely controlled to a desired level corresponding to the elapsed time. Thus, the etch amount is kept uniform regardless of the elapsed time.

Further, unlike the conventional examples, there is no need of replacing the cleaning solution flowing through the cleaning solution circulation path every time after a certain period has elapsed since the cleaning solution was fed into the cleaning solution circulation path. Therefore, replacement of the cleaning solution is carried out less frequently. As a result, the quantity of the cleaning solution used is reduced and the operating rate of the cleaning apparatus improves, thereby leading to reduction in cost of manufacturing electronic devices.

As to the apparatus for cleaning electronic devices according to the first aspect of the present invention, the etch time is preferably determined based on data concerning variations in etch amount of the target film that depend on time elapsed since the cleaning solution was fed into the cleaning solution circulation path until the cleaning solution is discharged from the cleaning solution circulation path.

By so doing, the target film is etched for suitable etch time corresponding to time elapsed since the cleaning solution was fed into the cleaning solution circulation path (i.e., lifetime).

As to the apparatus for cleaning electronic devices according to the first aspect of the present invention, it is preferable that the cleaning chamber includes therein a holder which supports the target substrate rotatably and a nozzle which communicates with the cleaning solution circulation line and through which the cleaning solution is fed onto the target substrate, and the etch time is determined based on data concerning variations in etch amount of the target film that depend on cumulative time spent for etching the target substrate since the cleaning solution was fed into the cleaning solution circulation path.

By so doing, when the single-wafer cleaning apparatus is used as the cleaning apparatus according to the first aspect of the present invention, the target film is etched for suitable etch time corresponding to the sum of durations spent for etching the target film since the cleaning solution was fed into the cleaning solution circulation path (i.e., cumulative time).

An apparatus for cleaning electronic devices according to the second aspect of the present invention includes: a cleaning solution circulation path which circulates a cleaning solution therein for reuse and includes a cleaning solution circulation line which is provided with a temperature regulator mechanism for controlling the temperature of the cleaning solution and a cleaning chamber in which the target substrate is cleaned; and a control unit for measuring time elapsed since the cleaning solution was fed into the cleaning solution circulation path and determining etching temperature based on the amount of a target film on the target substrate etched by the cleaning solution, the amount varying depending on the elapsed time, wherein the target substrate is etched in the cleaning chamber using the cleaning solution controlled at the etching temperature determined by the control unit.

The cleaning apparatus according to the second aspect of the present invention includes the control unit. The control unit determines suitable etching temperature based on variations in amount of the target film etched by the cleaning solution and variations in amount of the target film etched by the remainder of the cleaning solution after the etching step. Further, in the cleaning solution circulation path of the cleaning apparatus according to the second aspect of the present invention, the temperature of the cleaning solution is controlled by the temperature regulator mechanism.

Therefore, in the cleaning chamber of the cleaning apparatus according to the second aspect of the present invention, a temperature-controlled cleaning solution is used. Therefore, the target film is etched at a suitable etching temperature corresponding to the elapsed time.

As a result, the etch rate of the target film will not vary with a change in elapsed time, whereby the target film is etched under the suitable etching condition corresponding to the elapsed time. This surely prevents the etch amount of the target film from varying with the change in elapsed time. As a result, the etch amount of the target film is surely controlled to a desired level corresponding to the elapsed time. Thus, the etch amount is kept uniform regardless of the elapsed time.

Further, unlike the conventional examples, there is no need of replacing the cleaning solution flowing through the cleaning solution circulation path every time after a certain period has elapsed since the cleaning solution was fed into the cleaning solution circulation path. Therefore, replacement of the cleaning solution is carried out less frequently. As a result, the quantity of the cleaning solution used is reduced and the operating rate of the cleaning apparatus improves, thereby leading to reduction in cost of manufacturing electronic devices.

As to the apparatus for cleaning electronic devices according to the second aspect of the present invention, the control unit preferably sends data of the determined etching temperature to the temperature regulator mechanism.

By so doing, the target film is etched at a suitable etching temperature corresponding to the elapsed time as determined by the control unit.

As to the apparatus for cleaning electronic devices according to the second aspect of the present invention, the etching temperature is preferably determined based on data concerning variations in etch amount of the target film that depend on time elapsed since the cleaning solution was fed into the cleaning solution circulation path until the cleaning solution is discharged from the cleaning solution circulation path.

By so doing, the target film is etched at a suitable etching temperature corresponding to time elapsed since the cleaning solution was fed into the cleaning solution circulation path (i.e., lifetime).

As to the apparatus for cleaning electronic devices according to the second aspect of the present invention, it is preferable that the cleaning chamber includes therein a holder which supports the target substrate rotatably and a nozzle which communicates with the cleaning solution circulation line and through which the cleaning solution is fed onto the target substrate, and the etching temperature is determined based on data concerning variations in etch amount of the target film that depend on cumulative time spent for etching the target substrate since the cleaning solution was fed into the cleaning solution circulation path.

By so doing, when the single-wafer cleaning apparatus is used as the cleaning apparatus according to the second aspect of the present invention, the target film is etched at a suitable etching temperature corresponding to the sum of durations spent for etching the target film since the cleaning solution was fed into the cleaning solution circulation path (i.e., cumulative time).

As described above, with use of the apparatus and method for cleaning electronic devices according to the first or second aspect of the present invention, the etch time or etching temperature is determined based on variations in amount of the target film etched by the cleaning solution and variations in amount of the target film etched by the remainder of the cleaning solution after the etching step. As a result, the target film is etched at a desired etching temperature or for desired etch time.

Since the target film is etched under the suitable etching condition corresponding to the elapsed time, the etch amount of the target film is surely prevented from varying depending on the change in elapsed time. Since the etch amount of the target film is surely controlled to a desired level corresponding to the elapsed time, the etch amount is kept uniform regardless of the elapsed time.

Further, unlike the conventional examples, there is no need of replacing the cleaning solution flowing through the cleaning solution circulation path every time after a certain period has elapsed since the cleaning solution was fed into the cleaning solution circulation path. Therefore, replacement of the cleaning solution is carried out less frequently. As a result, the quantity of the cleaning solution used is reduced and the operating rate of the cleaning apparatus improves, leading to reduction in cost of manufacturing electronic devices.

### BRIEF DESCRIPTION OF THE DRAWINGS

FIG. 1 is a sectional view illustrating the structure of a cleaning apparatus for electronic devices according to Embodiment 1 of the present invention.

FIG. 2 is a view illustrating the specific structure of a circulation bath of the cleaning apparatus according to Embodiment 1 of the present invention.

FIG. 3 is a graph illustrating correlation between lifetime and etch amount found when the cleaning apparatus according to Embodiment 1 of the present invention is used.

FIG. 4 is a graph illustrating correlation between etch time and etch amount found when the cleaning apparatus according to Embodiment 1 of the present invention is used.

FIGS. 5A and 5B are diagrams illustrating processing flows in a control unit provided in the cleaning apparatus according to Embodiment 1 of the present invention.

FIG. 6 is a sectional view illustrating the structure of a cleaning apparatus for electronic devices according to Embodiment 2 of the present invention.

FIGS. 7A and 7B are diagrams illustrating processing flows in a CIM system connected to the cleaning apparatus according to Embodiment 2 of the present invention.

FIG. 8 is a graph illustrating correlation between lifetime and etch rate found when the cleaning apparatus for electronic devices according to Embodiment 3 of the present invention is used.

FIG. 9 is a graph illustrating correlation between etch time and etch amount found when the cleaning apparatus according to Embodiment 3 of the present invention is used and lifetime is 0 minute.

FIG. 10 is a graph illustrating correlation between etch time and etch amount found when the cleaning apparatus according to Embodiment 3 of the present invention is used and lifetime is 1440 minutes.

FIGS. 11A to 11D are sectional views of a major part illustrating the steps of a method for cleaning electronic devices according to Embodiment 4 of the present invention.

FIG. 12 is a graph illustrating correlation between 1/(273+Tj) and Ln(Rj) found when a cleaning apparatus for electronic devices according to Embodiment 6 of the present invention is used.

FIG. 13 is a sectional view illustrating the structure of a cleaning apparatus for electronic devices according to Embodiment 7 of the present invention.

FIG. 14 is a graph illustrating correlation between cumulative time and etch amount found when the cleaning apparatus according to Embodiment 7 of the present invention is used.

FIG. 15 is a graph illustrating correlation between etch time and etch amount found when the cleaning apparatus according to Embodiment 7 of the present invention is used.

FIGS. 16A and 16B are diagrams illustrating processing flows in a control unit provided in the cleaning apparatus according to Embodiment 7 of the present invention.

FIG. 17 is a sectional view illustrating the structure of a cleaning apparatus for electronic devices according to Embodiment 8 of the present invention.

FIGS. 18A and 18B are diagrams illustrating processing flows in a CIM system connected to the cleaning apparatus according to Embodiment 8 of the present invention.

FIG. 19 is a graph illustrating correlation between cumulative time and etch rate found when a cleaning apparatus for electronic devices according to Embodiment 9 of the present invention is used.

FIG. 20 is a graph illustrating correlation between etch time and etch amount found when the cleaning apparatus according to Embodiment 9 of the present invention is used and cumulative time is 0 minute.

FIG. 21 is a graph illustrating correlation between etch time and etch amount found when the cleaning apparatus according to Embodiment 9 of the present invention is used and cumulative time is 900 minutes.

FIGS. 22A to 22C are sectional views of a major part illustrating the steps of a method for cleaning electronic devices according to Embodiment 10 of the present invention.

FIG. 23 is a graph illustrating correlation between 1/(273+To) and Ln(Ro) found when a cleaning apparatus for electronic devices according to Embodiment 12 of the present invention is used.

FIG. 24 is a view illustrating the structure of a batch-type cleaning apparatus according to a first conventional example.

FIG. 25 is a view illustrating the specific structure of a circulation bath of the batch-type cleaning apparatus according to the first conventional example.

FIG. 26 is a graph illustrating correlation between lifetime and etch amount found when the batch-type cleaning apparatus according to the first conventional example is used.

FIG. 27 is a view illustrating the structure of a single-wafer cleaning apparatus according to the first conventional example.

FIG. 28 is a graph illustrating correlation between cumulative time and etch amount found when the single-wafer cleaning apparatus according to the first conventional example is used.

FIG. 29 is a schematic view illustrating the structure of a cleaning apparatus for electronic devices according to the second conventional example.

FIG. 30 is a graph schematically illustrating a relationship between elapsed time and etch rate and a relationship between elapsed time and hydrofluoric acid (HF) concentration established when the cleaning apparatus according to the second conventional example is used.

### DETAILED DESCRIPTION OF THE INVENTION

Hereinafter, with reference to the drawings, preferred embodiments of the present invention are described.

### EMBODIMENT 1

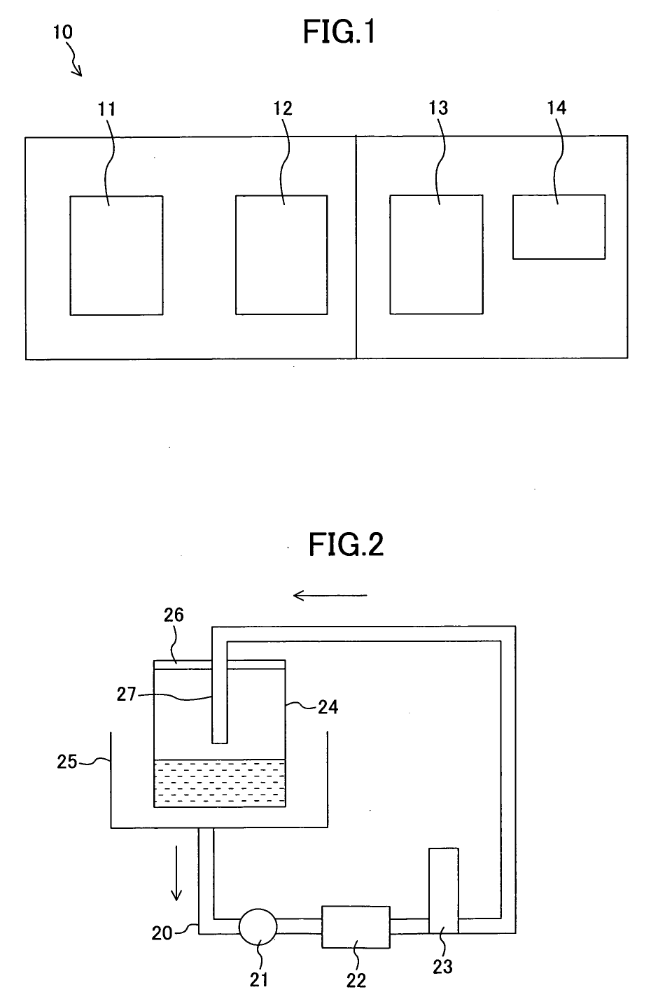

Hereinafter, with reference to FIGS. 1 and 2, an explanation of the structure of a cleaning apparatus for electronic devices according to Embodiment 1 of the present invention is provided.

FIG. 1 is a sectional view illustrating the structure of the cleaning apparatus according to Embodiment 1 of the present invention.

FIG. 2 is a sectional view illustrating the specific structure of a circulation bath of the cleaning apparatus according to Embodiment 1 of the present invention.

As shown in FIG. 1, the cleaning apparatus 10 of this embodiment includes a circulation bath 11, a rinsing bath 12, a dry bath 13 and a control unit 14. Specifically, the cleaning apparatus 10 is a combination of the batch-type cleaning apparatus 100 according to the first conventional example and the control unit 14.

As shown in FIG. 2, in the circulation bath 11, a circulation path including a circulation part and a cleaning part is provided. A cleaning solution is circulated through the circulation part and a target substrate is cleaned using the cleaning solution in the cleaning part. Specifically, the circulation part includes a circulation line (cleaning solution circulation line) 20, a circulation pump 21, an electronic thermoregulator 22 and a filter 23. The cleaning part includes an inner treatment bath (cleaning chamber) 24, an outer treatment bath 25, a bath cover 26 and a cleaning solution nozzle 27.

Hereinafter, referring to FIGS. 1 and 2, an explanation of a method for cleaning electronic devices using the cleaning apparatus of Embodiment 1 of the present invention is provided.

First, a cleaning solution is fed into the circulation line 20 in the circulation bath 11. The temperature of the cleaning solution fed into the circulation line 20 is adjusted by the electronic thermoregulator 22 provided on the circulation line 20. The cleaning solution whose temperature (etching temperature) has been controlled by the electronic thermoregulator 22 is fed from the circulation line 20 into the inner treatment bath 24 through the cleaning solution nozzle 27 and retained in the inner treatment bath 24.

Then, a target substrate is immersed in the cleaning solution contained in the inner treatment bath 24 for desired etch time to etch a target film on the target substrate. The cleaning solution used for cleaning the target substrate is circulated along the circulation line 20 and reused in the inner treatment bath 24.

A condition for etching the target film (e.g., etch time) is controlled by the control unit 14 provided in the cleaning apparatus 10. Specifically, the control unit 14 measures time elapsed since the cleaning solution was fed into the circulation line 20 (hereinafter the time is referred to as {lifetime}). Then, the control unit 14 determines certain etch time corresponding to the measured lifetime. In this way, suitable etching condition corresponding to the lifetime is determined.

The target substrate is immersed in the cleaning solution contained in the inner treatment bath 24 for the desired etch time corresponding to the lifetime as determined by the control unit 14. Consequently, the target film on the target substrate is etched.

Subsequently, the target substrate which has been subjected to etching in the circulation bath 11 is rinsed with water in the rinsing bath 12. In this step, the cleaning solution remaining on the target substrate is removed and at the same time, residues of the target film are etched by the remaining solution. That is, the target film is etched not only by the cleaning solution in the circulation bath 11 but also by the remainder of the cleaning solution in the rinsing bath 12.

Then, the substrate rinsed in the rinsing bath 12 is dried in the dry bath 13.

Hereinafter, a detailed explanation is given of evaluations of correlation between lifetime and etch amount and correlation between etch time and etch amount to determine the etch time corresponding to the lifetime of the cleaning solution in using the cleaning apparatus of Embodiment 1.

In order to evaluate the correlations, a buffered hydrofluoric acid solution (containing 0.10% HF and 39.0% NH₄F) is used as the cleaning solution to be fed into the circulation line 20 of the cleaning apparatus of Embodiment 1. The buffered hydrofluoric acid solution (hereinafter referred to as BHF solution) is controlled at a certain etching temperature (e.g., 21° C.) by the electronic thermoregulator 22 provided on the circulation line 20.

First, for evaluation of the correlation between lifetime and etch amount under the above-described conditions, the target substrate is immersed in the BHF solution contained in the inner treatment bath 24 for certain etch time (e.g., 3 minutes) to etch the target film (thermal oxide film) on the target substrate.

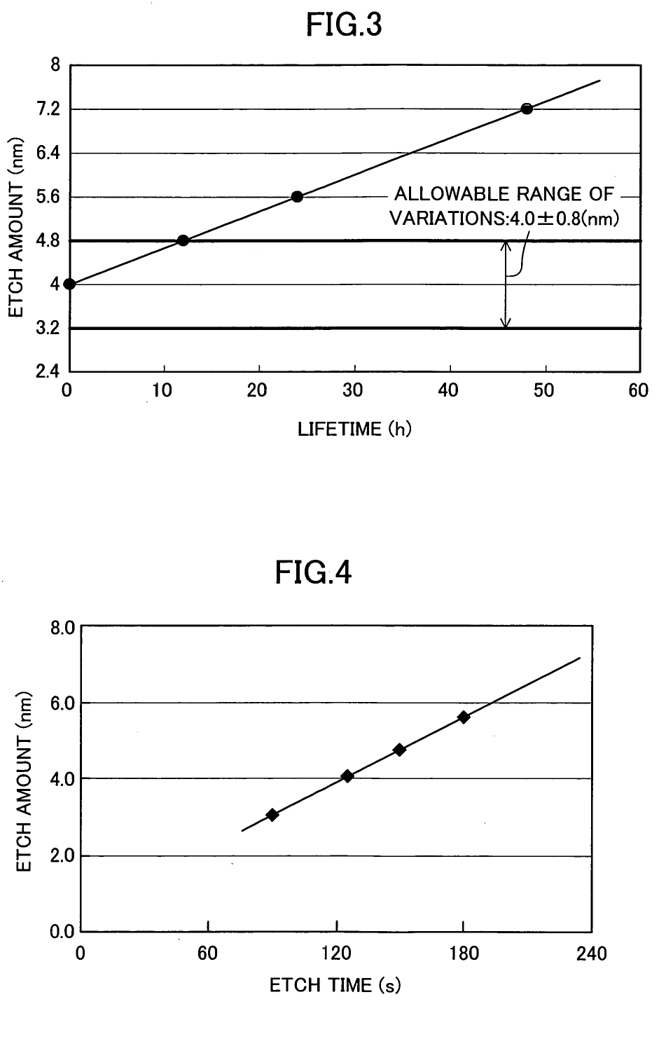

By measuring the etch amounts of the thermal oxide film corresponding to different lifetimes, the correlation between lifetime and etch amount is evaluated. Hereinafter, referring to Table 1 and FIG. 3, an explanation is given of the correlation between lifetime and etch amount found when the cleaning apparatus of Embodiment 1 is used.

Table 1 shows the etch amounts of the target film corresponding to different lifetimes obtained when the cleaning apparatus of Embodiment 1 of the present invention is used.

FIG. 3 is a graph illustrating the correlation between lifetime and etch amount found when the cleaning apparatus of Embodiment 1 of the present invention is used.

As shown in Table 1, measurement of the amount of the thermal oxide film etched by the BHF solution is carried out after different lifetimes (0, 12, 24 and 48 hours) have elapsed. Then, the etch amounts of the thermal oxide film corresponding to the lifetimes are plotted as shown in FIG. 3 to evaluate the correlation between lifetime and etch amount.

TABLE 1

| Lifetime (h) | Etch amount (nm) |
|---|---|
| 0 | 4.0 |
| 12 | 4.8 |
| 24 | 5.6 |
| 48 | 7.2 |

FIG. 3 shows that the etch amount of the thermal oxide film increases at a certain rate with an increase in lifetime. Specifically, 4.0 nm of the thermal oxide film is etched by the BHF solution when the lifetime is 0 hour, while 5.6 nm of the thermal oxide film is etched by the BHF solution when the lifetime of 24 hours has elapsed. Thus, the results show that the BHF solution which has spent 24-hour lifetime etches the thermal oxide film more than the BHF solution which has spent 0-hour lifetime.

Now, a cause of the increase in etch amount of the thermal oxide film with an increase in lifetime is described below.

The BHF solution made of HF and NH₄F is dissociated into NH₃, H⁺ and HF₂⁻ and equilibrated in this state. Therefore, the BHF solution contains HF, NH₄F, NH₃, H⁺ and HF₂⁻.

Among them, NH₃ has a lower vapor pressure than the other components (HF, NH₄F, H⁺ and HF₂⁻) and therefore is likely to evaporate. For this reason, from the BHF solution which is fed into the circulation line 20 and retained in the inner treatment bath 24, NH₃ selectively evaporates with an increase in retention time. That is, NH₃ evaporates to decrease the NH₃ concentration in the BHF solution with an increase in lifetime.

As a result, the equilibrium of the BHF solution is shifted to the right (toward the system of formation) and a larger amount of HF₂⁻ is dissociated as shown in the equation (I). Accordingly, the concentration of HF₂⁻ as an etchant increases in the BHF solution.
HF+NH₄F→NH₃↑+H⁺+HF₂⁻ (I)

Since the HF₂⁻ concentration in the BHF solution increases with an increase in lifetime, the etch amount of the thermal oxide film also increases.

Specifically, as compared with a fresh BHF solution which has just fed into the circulation line 20, the BHF solution which has spent 24 hours after being fed into the circulation line 20 varies the composition thereof, i.e., the HF₂⁻ concentration increases. Therefore, the BHF solution which has spent 24-hour lifetime etches a larger amount of the thermal oxide film (5.6 nm) than the BHF solution which has spent 0-hour lifetime (4.0 nm).

Thus, from the evaluation of the correlation between lifetime and etch amount found when the cleaning apparatus of Embodiment 1 is used, it is indicated that the etch amount of the target film increases at a certain rate with an increase in lifetime.

Next, for evaluation of the correlation between etch time and etch amount under the above-described conditions, the target substrate is immersed in the BHF solution contained in the inner treatment bath 24 for an optionally selected lifetime (e.g., 24 hours) to etch the target film (thermal oxide film) on the target substrate.

By measuring the amounts of the thermal oxide film etched for different etch times, the correlation between etch time and etch amount found when the lifetime of the BHF solution is 24 hours is evaluated. Hereinafter, referring to Table 2 and FIG. 4, an explanation is given of the correlation between etch time and etch amount found when the cleaning apparatus of Embodiment 1 is used.

Table 2 shows the etch amounts of the target film corresponding to different etch times obtained when the cleaning apparatus of Embodiment 1 of the present invention is used.

FIG. 4 is a graph illustrating the correlation between etch time and etch amount found when the cleaning apparatus of Embodiment 1 of the present invention is used.

As shown in Table 2, the amounts of the thermal oxide film etched by the BHF solution for different etch times (180, 150, 120 and 90 seconds) are measured. Then, the etch amounts of the thermal oxide film corresponding to the etch times are plotted as shown in FIG. 4 to evaluate the correlation between etch time and etch amount.

TABLE 2

| Lifetime (h) | Etch time (s) | Etch amount (nm) |
|---|---|---|
| 0 | 180 | 4.0 |
| 24 | 180 | 5.6 |
| 24 | 150 | 4.8 |
| 24 | 120 | 4.0 |
| 24 | 90 | 3.1 |

FIG. 4 indicates that the etch amount of the thermal oxide film decreases at a certain rate with a decrease in etch time. Specifically, 5.6 nm of the thermal oxide film is etched when the etch time is 180 seconds, while 4.0 nm of the thermal oxide film is etched when the etch time is 120 seconds.

As shown in Table 1 and FIG. 3, under the same etch time condition (180 seconds), 4.0 nm of the thermal oxide film is etched by the BHF solution which has spent 0-hour lifetime, while 5.6 nm is etched by the BHF solution which has spent 24-hour lifetime. In this case, if the allowable range of variations in etch amount of the thermal oxide film is ±20%, i.e., 4.0±0.8 (nm) as shown in FIG. 3, the amount etched by the BHF solution which has spent 24-hour lifetime deviates from the allowable range.

Therefore, as shown in Table 2 and FIG. 4, if the etch time is changed from 180 seconds to 120 seconds when the lifetime of the BHF solution has reached 24 hours, the etch amount is surely controlled to 4.0 nm, which is the same etch amount when the lifetime is 0 hour.

In order to adjust the etch time as described above, the cleaning apparatus 10 of Embodiment 1 is provided with the control unit 14 which determines the etch time corresponding to the lifetime of the cleaning solution.

For example, as shown in Tables 1 and 2 and FIGS. 3 and 4, the control unit 14 determines the etch time of 180 seconds when the lifetime of the BHF solution is 0 hour, or the etch time of 120 seconds when the lifetime of the BHF solution is 24 hours.

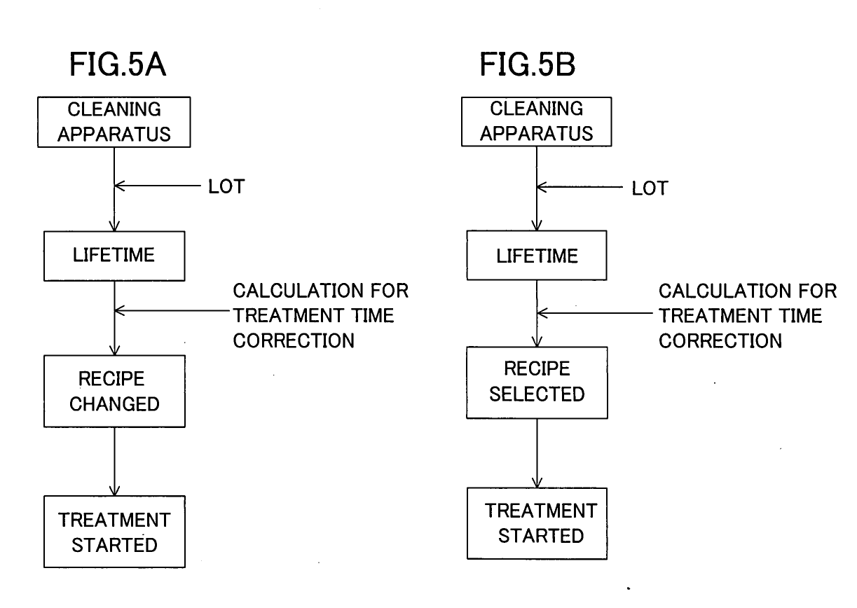

Hereinafter, referring to FIGS. 5A and 5B, processing flows in the control unit 14 provided in the cleaning apparatus 10 of Embodiment 1 will be explained.

FIGS. 5A and 5B are diagrams illustrating processing flows in the control unit 14 provided in the cleaning apparatus of Embodiment 1.

As shown in FIG. 5A, in lot processing, the control unit 14 first reads out time elapsed since the cleaning solution was fed into the circulation line 20, i.e., lifetime. Then, the control unit 14 determines an etching condition corresponding to the read-out lifetime, i.e., etch time, using a correction formula. Subsequently, the control unit 14 rewrites an etch time preset in a recipe (processing instructions) of the control unit 14 as the determined etch time.

In this way, the control unit 14 changes the etch time preset in the recipe into the desired etch time corresponding to the lifetime.

Then, in the circulation bath 11, the target substrate is immersed in the cleaning solution contained in the inner treatment bath 24 for the desired etch time to etch the target film on the target substrate.

For example, as described above, when the lifetime of the BHF solution is 0 hour, the etch time preset in the recipe is rewritten as 180 seconds. On the other hand, when the lifetime of the BHF solution is 24 hours, the etch time preset in the recipe is rewritten as 120 seconds. As a result, the thermal oxide film is etched for certain etch time corresponding to the lifetime of the BHF solution used. Thus, the etch amount of the thermal oxide film is fixed (4.0 nm) with reliability regardless of the lifetime.

Further, as shown in FIG. 5B, in lot processing, the control unit 14 first reads out time elapsed since the cleaning solution was fed into the circulation line 20, i.e., lifetime. Then, the control unit 14 determines an etching condition corresponding to the read-out lifetime, i.e., etch time, using a correction formula. Subsequently, based on the determined etch time, the control unit 14 selects a desired etch time from a plurality of etch times preset in a recipe (processing instructions) of the control unit 14.

In this way, the control unit 14 selects the desired etch time corresponding to the lifetime from the plurality of etch times previously set in the recipe.

Then, in the circulation bath 11, the target substrate is immersed in the cleaning solution contained in the inner treatment bath 24 for the desired etch time to etch the target film on the target substrate.

For example, when the lifetime of the BHF solution is 0 hour, the etch time of 180 seconds is selected from the plurality of etch times set in the recipe. On the other hand, when the lifetime of the BHF solution is 24 hours, the etch time of 120 seconds is selected from the plurality of etch times set in the recipe. As a result, the thermal oxide film is etched for suitable etch time corresponding to the lifetime of the BHF solution used. Thus, the etch amount of the thermal oxide film is fixed (4.0 nm) with reliability regardless of the lifetime.

As described above, the cleaning apparatus 10 of Embodiment 1 of the present invention is provided with the control unit 14 which determines suitable etch time corresponding to the lifetime of the cleaning solution used as shown in FIG. 5A or 5B. Further, in the inner treatment bath 24 of the cleaning apparatus 10, the target film is etched for the desired etch time determined by the control unit 14.

Therefore, even if the composition of the cleaning solution varies with a change in lifetime and the etch rate of the target film is changed, the control unit 14 controls the etch time based on the lifetime. As a result, the target film is etched under the suitable etching condition corresponding to the lifetime, i.e., the etch amount of the target film will not vary depending on the change in lifetime. Therefore, the etch amount of the target film is fixed with reliability regardless of the lifetime.

Further, unlike the conventional examples, there is no need of replacing the cleaning solution in the circulation line every time after a certain period of time has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 2

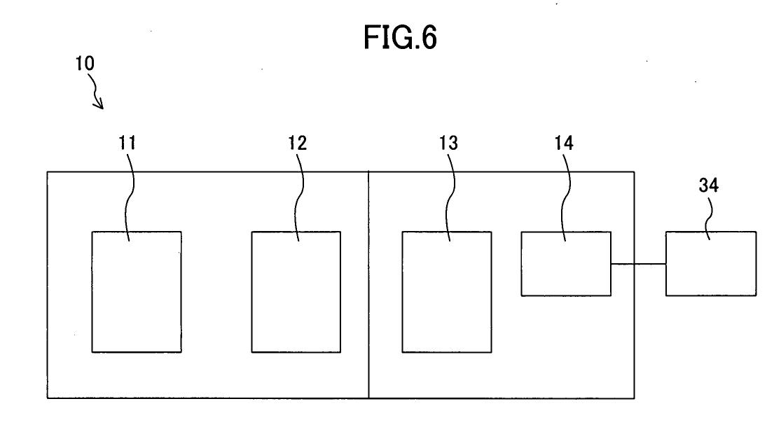

Hereinafter, with reference to FIG. 6, an explanation of the structure of a cleaning apparatus for electronic devices according to Embodiment 2 of the present invention is provided.

FIG. 6 is a sectional view illustrating the structure of the cleaning apparatus of Embodiment 2 of the present invention.

In FIG. 6, the same components as those of the cleaning apparatus described in Embodiment 1 are indicated by the same reference numerals. Therefore, in this embodiment, an explanation of the components already detailed in Embodiment 1 is omitted.

As shown in FIG. 6, the cleaning apparatus 10 of this embodiment includes a circulation bath 11, a rinsing bath 12, a dry bath 13 and a control unit 14. Further, a CIM (Computer Integrated Manufacturing) system 34 is connected to the cleaning apparatus 10 via the control unit 14. That is, the cleaning apparatus 10 of this embodiment is a combination of the batch-type cleaning apparatus 100 of the first conventional example and the CIM system 34 connected thereto via the control unit 14.

Hereinafter, with reference to Tables 1 and 2 and FIGS. 3 and 4, a brief explanation of a method for determining the etch time corresponding to the lifetime of a cleaning solution in the cleaning apparatus 10 of Embodiment 2 is provided.

As shown in Tables 1 and 2 and FIGS. 3 and 4, with use of the cleaning apparatus 10 of Embodiment 2, an intended amount (4.0 nm) of the thermal oxide film is surely etched in 180 seconds when the lifetime of the BHF solution is 0 hour. On the other hand, when the lifetime of the BHF solution is 24 hours, the intended amount (4.0 nm) of the thermal oxide film is surely etched in 120 seconds.

In order to adjust the etch time as described above, the cleaning apparatus 10 of Embodiment 2 is provided with the CIM system 34 connected thereto via the control unit 14. The CIM system 34 determines suitable etch time corresponding to the lifetime of the cleaning solution.

For example, as shown in Tables 1 and 2 and FIGS. 3 and 4, when the lifetime of the BHF solution is 0 hour, the CIM system 34 determines the etch time of 180 seconds. On the other hand, when the lifetime of the BHF solution is 24 hours, the CIM system 34 determines the etch time of 120 seconds.

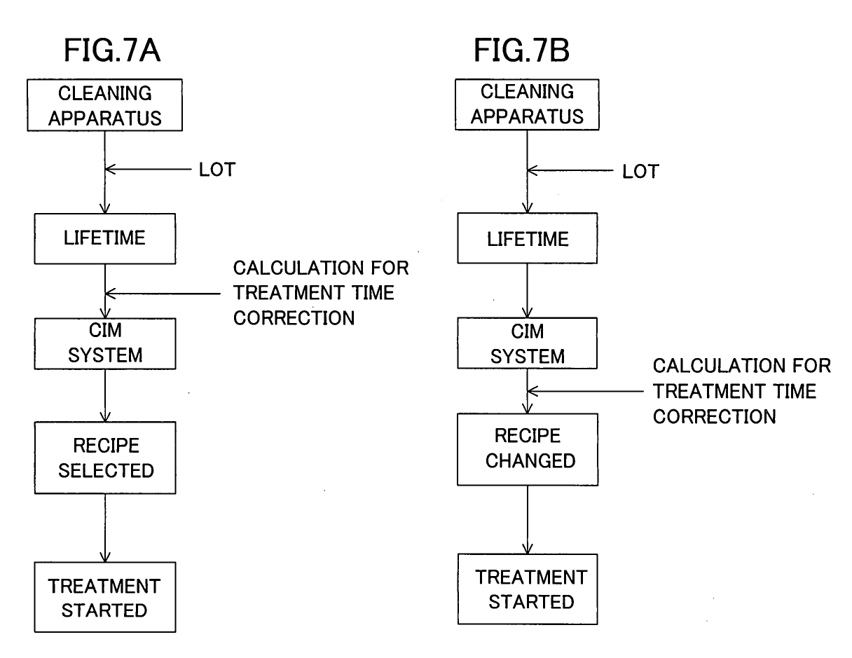

Hereinafter, referring to FIGS. 7A and 7B, an explanation of processing flows in the CIM system 34 connected to the cleaning apparatus 10 of Embodiment 2 is provided.

FIGS. 7A and 7B are diagrams illustrating processing flows in the CIM system 34 connected to the cleaning apparatus 10 of Embodiment 2.

As shown in FIG. 7A, first, in lot processing, the control unit 14 first reads out time elapsed since the cleaning solution was fed into the circulation line 20, i.e., lifetime. Then, upon receipt of the lifetime data from the control unit 14, the CIM system 34 determines an etching condition corresponding to the read-out lifetime, i.e., etch time, using a correction formula. Subsequently, based on the determined etch time, the CIM system 34 selects a desired etch time from a plurality of etch times preset in a recipe (processing instructions) of the control unit 14.

In this way, the control unit 14 selects the desired etch time corresponding to the lifetime from the plurality of etch times previously set in the recipe.

Then, in the circulation bath 11, the target substrate is immersed in the cleaning solution contained in the inner treatment bath 24 for the desired etch time to etch the target film on the target substrate.

Further, as shown in FIG. 7B, first, in lot processing, the control unit 14 first reads out time elapsed since the cleaning solution was fed into the circulation line 20, i.e., lifetime. Then, upon receipt of the lifetime data from the control unit 14, the CIM system 34 determines an etching condition corresponding to the read-out lifetime, i.e., etch time, using a correction formula. Subsequently, the CIM system 34 rewrites an etch time preset in a recipe (processing instructions) of the control unit 14 as the determined etch time.

In this way, the control unit 14 changes the etch time preset in the recipe into the desired etch time corresponding to the lifetime.

Then, in the circulation bath 11, the target substrate is immersed in the cleaning solution contained in the inner treatment bath 24 for the desired etch time to etch the target film on the target substrate.

As described above, the cleaning apparatus 10 of Embodiment 2 of the present invention is provided with the control unit 14 and the CIM system 34 is connected to the system via the control unit 14. The CIM system 34 determines the etch time corresponding to the lifetime of the cleaning solution as shown in FIG. 7A or 7B. Further, in the inner treatment bath 24 of the cleaning apparatus 10, the target film is etched for the desired etch time determined by the CIM system 34.

Therefore, even if the composition of the cleaning solution varies with a change in lifetime and the etch rate of the target film is changed, the CIM system 34 controls the etch time based on the lifetime. As a result, the target film is etched under the suitable etching condition corresponding to the lifetime, i.e., the etch amount of the target film will not vary depending on the change in lifetime. Therefore, the etch amount of the target film is fixed with reliability regardless of the lifetime.

Further, unlike the conventional examples, there is no need of replacing the cleaning solution in the circulation line every time after a certain period of time has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 3

Hereinafter, an explanation of a cleaning apparatus for electronic devices according to Embodiment 3 of the present invention is provided.

The cleaning apparatus of Embodiment 3 is composed of the batch-type cleaning apparatus of the first conventional example and a control unit 14 added thereto like the cleaning apparatus 10 of Embodiment 1. Or alternatively, the cleaning apparatus of Embodiment 3 is composed of the batch-type cleaning apparatus of the first conventional example and a CIM system 34 connected thereto via the control unit 14 like the cleaning apparatus 10 of Embodiment 2.

Therefore, in this embodiment, an explanation of the details of the cleaning apparatus already described in Embodiments 1 and 2 is omitted.

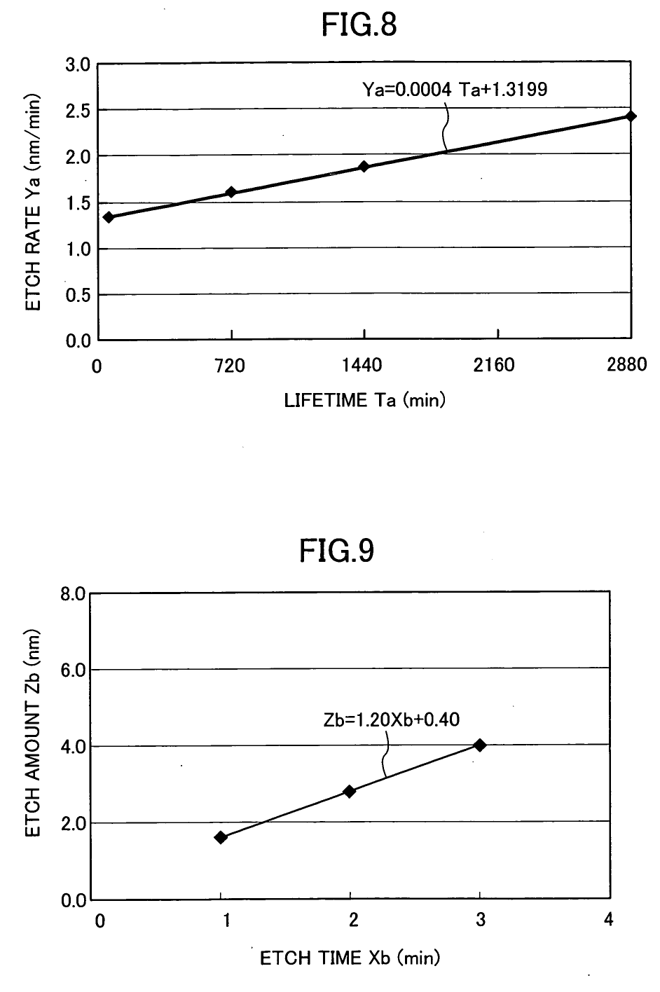

Hereinafter, with reference to Tables 3, 4 and 5 and FIGS. 8, 9 and 10, an explanation is given of a correction formula for determining the etch time corresponding to the lifetime of the cleaning solution when the cleaning apparatus of Embodiment 3 is used.

In order to derive the correction formula for the cleaning apparatus of the present embodiment, a target substrate is immersed for certain etch time (e.g., 180 seconds) in a BHF solution (containing 0.10% HF and 39.0% NH₄F) which is controlled at a certain etching temperature (e.g., 21° C.) and contained in an inner treatment bath 24, thereby etching a target film (thermal oxide film) on the target substrate.

First, under the above-described conditions, the following measurement is carried out to obtain an increase coefficient (B) of the etch rate of the thermal oxide film.

The increase coefficient (B) is the rate at which the etch rate of the thermal oxide film increases with an increase in lifetime.

Table 3 shows the etch rates of the target film corresponding to different lifetimes when the cleaning apparatus of Embodiment 3 is used.

FIG. 8 is a graph illustrating correlation between lifetime and etch rate found when the cleaning apparatus of Embodiment 3 is used.

As shown in Table 3, measurement of the etch rate of the thermal oxide film is carried out after different lifetimes (0, 720, 1440 and 2880 minutes) have elapsed. Then, the measured etch rates corresponding to the lifetimes are plotted as shown in FIG. 8 to evaluate the correlation between lifetime and etch rate.

TABLE 3

| | |
|---|---|
| Lifetime | Etch rate |

| (h) | (min) | (nm/min) |
|---|---|---|
| 0 | 0 | 1.3 |
| 12 | 720 | 1.6 |
| 24 | 1440 | 1.9 |
| 48 | 2880 | 2.4 |

Provided that the etch rate of the thermal oxide film when the lifetime is Ta (min) is Ya (nm/min), a relationship between the lifetime Ta and the etch rate Ya of the thermal oxide film is represented by a linear function. Therefore, the following approximate equation [a] is derived.
Ya=0.0004Ta+1.3199 [a]

From the approximate equation [a], the increase coefficient (B) of the etch rate of the thermal oxide film is obtained. Thus, the rate at which the BHF solution etches the thermal oxide film increases by 0.0004 (nm) per lifetime (min).

In this way, the composition of the BHF solution varies with an increase in lifetime, whereby the etch amount of the thermal oxide film increases. As a result, the etch rate of the thermal oxide film increases.

Then, under the above-described conditions, the following measurement is carried out to obtain the etch rate (A) and the additional etch amount (C) of the thermal oxide film.

The etch rate (A) is the rate at which the amount of the thermal oxide film etched by the BHF solution which has just fed into the circulation line increases with an increase in etch time.

The additional etch amount (C) is the amount of the thermal oxide film additionally etched during the rinsing step by the remainder of the BHF solution which has just fed into the circulation line.

Table 4 shows the etch amounts of the target film corresponding to different etch times when the lifetime of the BHF solution is 0 minute in the cleaning apparatus according to Embodiment 3.

FIG. 9 is a graph illustrating correlation between etch time and etch amount found when the lifetime of the BHF solution is 0 minute in the cleaning apparatus of Embodiment 3.

As shown in Table 4, the amounts of the thermal oxide film etched by the BHF solution which has just fed into the circulation line, i.e., which has spent 0-minute lifetime, for different etch times (1, 2 and 3 minutes) are measured. Then, the etch amounts corresponding to the different etch times are plotted as shown in FIG. 9 to evaluate the correlation between etch time and etch amount found when the lifetime of the BHF solution is 0 minute.

TABLE 4

| Etch time (min) | Etch amount (nm) |
|---|---|
| 1.0 | 1.6 |
| 2.0 | 2.8 |
| 3.0 | 4.0 |

Provided that the amount of the thermal oxide film etched for the etch time Xb (min) is Zb (nm), a relationship between the etch time Xb and the etch amount Zb where the lifetime is 0 minute is represented by a linear function. Therefore, the following approximate equation [b] is derived.
Zb=1.20Xb+0.40 [b]

From the approximate equation [b], the etch rate (A) of the thermal oxide film is obtained. Thus, the amount of the thermal oxide film etched by the BHF solution which has spent 0-minute lifetime increases by 1.20 (nm) per etch time (min).

Further, from the approximate equation [b], the additional etch amount (C) of the thermal oxide film is obtained. Thus, the amount of the thermal oxide film additionally etched during the rinsing step by the remainder of the BHF solution which has spent 0-minute lifetime is 0.40 (nm).

Then, under the above-described conditions, the following measurement is carried out to obtain the additional etch rate (D) of the thermal oxide film.

The additional etch rate (D) is the rate at which the amount of the thermal oxide film etched by the remainder of the BHF solution during the rinsing step (i.e., the additional etch amount of the thermal oxide film) increases with an increase in lifetime.

Table 5 shows the etch amounts of the target film corresponding to different etch times when the lifetime of the BHF solution is 1440 minutes in the cleaning apparatus of Embodiment 3.

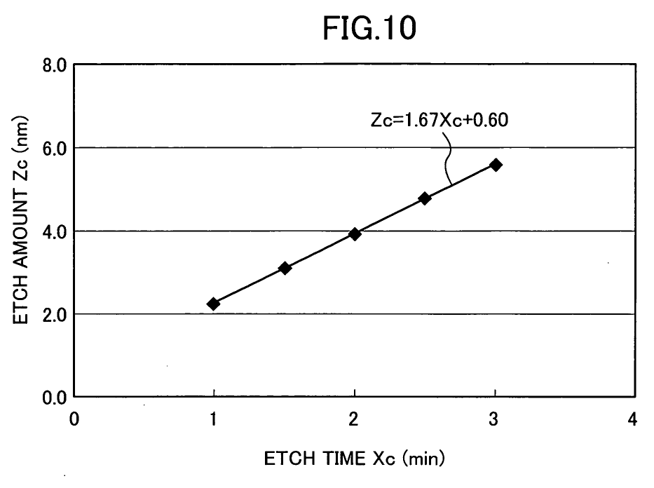

FIG. 10 is a graph illustrating correlation between etch time and etch amount found when the lifetime of the BHF solution is 1440 minutes in the cleaning apparatus of Embodiment 3.

As shown in Table 5, the amounts of the thermal oxide film etched by the BHF solution which has spent optionally selected lifetime (e.g., 1440 minutes) for different etch times (1, 2 and 3 minutes) are measured. Then, the measured etch amounts corresponding to the etch times are plotted as shown in FIG. 10 to evaluate the correlation between etch time and etch amount found when the lifetime of the BHF solution is 1440 minutes.

TABLE 5

| Etch time (min) | Etch amount (nm) |
|---|---|
| 1.0 | 2.3 |
| 2.0 | 3.9 |
| 3.0 | 5.6 |

Provided that the amount of the thermal oxide film etched for the etch time Xc (min) is Zc (nm), a relationship between the etch time Xc and the etch amount Zc where the lifetime is 1440 minutes is represented by a linear function. Therefore, the following approximate equation [c] is derived.
Zc=1.67Xc+0.60 [c]

The approximate equation [c] indicates that the amount of the thermal oxide film etched during the rinsing step by the remainder of the BHF solution which has spent 1440-minute lifetime is 0.60 (nm).

As described above, the composition of the BHF solution varies with an increase in lifetime, and therefore the amount of the thermal oxide film etched by the BHF solution increases. In a like manner, the amount of the thermal oxide film etched by the remainder of the BHF solution (hereinafter referred to as the additional etch amount) also increases with an increase in lifetime.

The approximate equation [b] of FIG. 9 shows that the additional etch amount of the thermal oxide film when the lifetime is 0 minute is 0.40 (nm), while the approximate equation [c] of FIG. 10 shows that the additional etch amount of the thermal oxide film when the lifetime is 1440 minutes is 0.60 (nm). Thus, the additional etch amount of the thermal oxide film increases with an increase in lifetime.

Therefore, provided that the additional etch amount of the thermal oxide film when the lifetime is Td (min) is Wd (nm), the relationship between the lifetime Tb and the additional etch amount Wd is represented by a linear function. Thus, the following approximate equation [d] is derived.
Wd=(1.39×10⁻⁴)×Td+0.40 [d]

From the approximate equation [d], the additional etch rate (D) of the thermal oxide film is obtained. Thus, the amount of the thermal oxide film additionally etched by the remainder of the BHF solution during the rinsing step (the additional etch amount) increases by 1.39×10⁻⁴ (nm) per lifetime (min).

From the approximate equations [a], [b] and [d], the etch time corresponding to the lifetime is obtained using the following formula [1]:
Etch time={Intended etch amount−[Additional etch amount (C)+Additional etch rate (D)×Lifetime]}/{Etch rate (A)+Increase coefficient (B)×Lifetime} [1]

In the formula [1], the increase coefficient (B) is a value indicating the rate at which the etch rate of the target film increases with an increase in lifetime and obtained from the approximate equation [a]. For example, the increase coefficient (B) may be 0.0004 (nm/min²).

The etch rate (A) is a value indicating the rate at which the amount of the target film etched by the cleaning solution just fed into the circulation line (cleaning solution circulation line) increases with an increase in etch time and obtained from the approximate equation [b]. For example, the etch rate (A) may be 1.2 (nm/min).

The additional etch amount (C) is the amount of the target film additionally etched during the rinsing step by the remainder of the cleaning solution just fed into the circulation line and obtained from the approximate equation [b]. For example, the additional etch amount (C) may be 0.4 (nm).

The additional etch rate (D) is a value indicating the rate at which the additional etch amount of the target film increases with an increase in lifetime and obtained from the approximate equation [d]. For example, the additional etch rate (D) may be 1.39×10⁻⁴ (nm/min²).

In the control unit 14 or the CIM system 34 of the cleaning apparatus of Embodiment 3, the formula [1] is set as a correction formula and suitable etch time corresponding to the lifetime is determined based on the formula [1].

For example, as shown in Tables 1 and 2 and FIGS. 3 and 4, the control unit 14 or the CIM system 34 determines, using the formula [1], the etch time of 180 seconds when the lifetime of the BHF solution is 0 minute, or the etch time of 120 seconds when the lifetime of the BHF solution is 1440 minutes.

As described above, the control unit or the CIM system of the cleaning apparatus of Embodiment 3 determines the etch time corresponding to the lifetime using the formula [1] as shown in FIG. 5A or 5B and FIG. 7A or 7B. Then, in the inner treatment bath of the cleaning apparatus of this embodiment, the target film is subjected to etching for the desired etch time determined by the control unit or the CIM system.

Therefore, even if the composition of the cleaning solution varies with a change in lifetime and the etch rate of the target film is changed, the control unit or the CIM system controls the etch time based on the lifetime. As a result, the target film is etched under the suitable etching condition corresponding to the lifetime, i.e., the etch amount of the target film is prevented from varying with the change in lifetime. Therefore, the etch amount of the target film is fixed with reliability regardless of the lifetime.

Further, unlike the conventional examples, there is no need of replacing the cleaning solution in the circulation line every time after a certain period of time has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 4

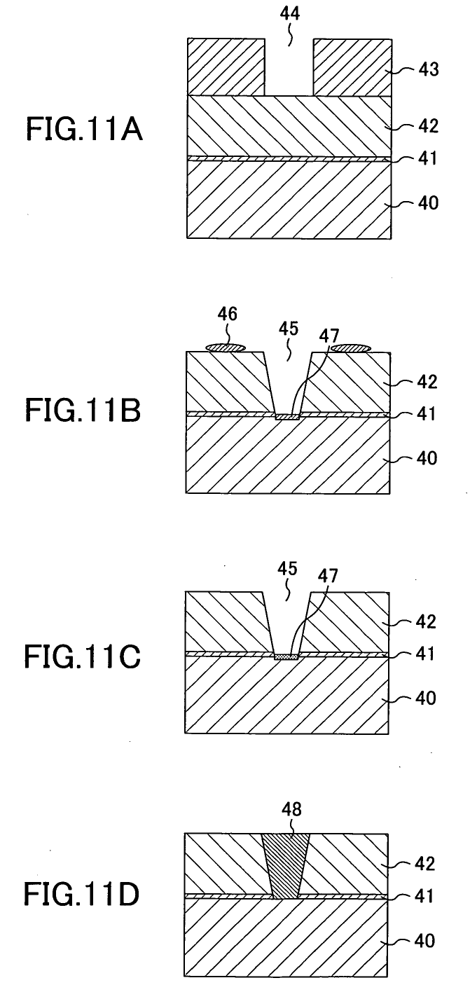

Hereinafter, with reference to FIGS. 11A to 11D, an explanation of a method for cleaning electronic devices using a cleaning apparatus according to Embodiment 4 of the present invention is provided.

FIGS. 11A to 11D are sectional views of a major part illustrating the steps of a method for cleaning the electronic devices according to Embodiment 4 of the present invention.

As shown in FIG. 11A, a nitride film 41 and a CVD oxide film 42 are formed in this order on a silicon substrate 40. Then, a resist 43 applied onto the CVD oxide film 42 is patterned into a desired shape, thereby forming an opening 44 which exposes part of the CVD oxide film 42. Through the opening 44, the CVD oxide film 42 and the nitride film 41 are removed by dry etching, thereby forming a contact hole 45 of a desired shape.

Then, after the dry etching, ashing is carried out with oxygen plasma to remove resist residues 46 shown in FIG. 11B. Then, the substrate is cleaned with SPM (sulfuric acid-hydrogen peroxide mixture: H₂SO₄/H₂O₂), and then with APM (ammonium hydrogen peroxide mixture: NH₄OH/H₂O₂).

Then, as shown in FIG. 11C, using the cleaning apparatus of Embodiment 4, a natural oxide film 47 is completely removed and at the same time, the CVD oxide film 42 is further etched to provide the contact hole 45 with a desired diameter.

For example, a BHF solution (containing 0.10% HF and 39.0% NH₄F) controlled at 21° C. is used as the cleaning solution for the cleaning apparatus of Embodiment 4 and the target substrate (silicon substrate 40) is immersed in the BHF solution contained in the inner treatment bath 24 of the cleaning apparatus for certain etch time corresponding to the lifetime of the BHF solution used. In this way, the target films (the natural oxide film 47 and the CVD oxide film 42) on the silicon substrate 40 are etched.

Specifically, as shown in Tables 1 and 2 and FIGS. 3 and 4, the silicon substrate 40 is immersed in the BHF solution in the inner treatment bath for 180 seconds when the lifetime of the BHF solution is 0 hour. On the other hand, the silicon substrate 40 is immersed in the BHF solution in the inner treatment bath for 120 seconds when the lifetime of the solution is 24 hours.

By etching the natural oxide film 47 and the CVD oxide film 42 with the BHF solution for the etch time corresponding to the lifetime, the natural oxide film 47 generated at the bottom of the contact hole 45 is completely removed and the CVD oxide film 42 is etched by 4.0 nm in terms of thermal oxide film. Thus, the contact hole 45 is provided with a desired diameter.

Then, as shown in FIG. 11D, a polysilicon film is formed on the CVD oxide film 42 to fill the contact hole 45 and then flattened by CMP to form a polysilicon plug 48.

As described above, with use of the cleaning apparatus of Embodiment 4, the target films are etched for certain etch time corresponding to the lifetime of the cleaning solution. As a result, the etch amount is fixed (4.0 nm in terms of thermal oxide film), whereby the standard of the diameter of the contact hole is satisfied irrespective of the lifetime.

Therefore, even if the composition of the cleaning solution varies with an increase in lifetime during the removal of the natural oxide film 47 and the etching of the CVD oxide film 42, the CVD oxide film 42 is not etched too much. Therefore, the diameter of the contact hole will not increase too much.

Since the CVD oxide film 42 is not etched too much and the diameter of the contact hole does not increase too much, adjacent contact holes 45 will not come into contact with each other, thereby preventing product defects caused by contact between adjacent contact holes 45. As a result, the yield of the electronic devices improves.

As described above, according to the cleaning apparatus of Embodiment 4, the target films are etched under the etching condition corresponding to the lifetime of the cleaning solution. Therefore, even if the composition of the cleaning solution varies with a change in lifetime, the etch amount of the target films is fixed with reliability.

Further, unlike the conventional examples, there is no need of replacing the cleaning solution flowing through the circulation line every time after a certain period has elapsed since the cleaning solution was fed into the circulation line. Therefore, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 5

Hereinafter, an explanation of a cleaning apparatus for electronic devices according to Embodiment 5 of the present invention is provided.

The cleaning apparatus of Embodiment 5 is composed of the batch-type cleaning apparatus of the first conventional example and a control unit 14 added thereto like the cleaning apparatus 10 of Embodiment 1. Or alternatively, the cleaning apparatus of Embodiment 5 is composed of the batch-type cleaning apparatus of the first conventional example and a CIM system 34 connected thereto via the control unit 14 like the cleaning apparatus 10 of Embodiment 2.

Therefore, in this embodiment, an explanation of the details of the cleaning apparatus already described in Embodiments 1 and 2 is omitted.

The control unit or the CIM system of the cleaning apparatus of Embodiment 5 determines etching temperature corresponding to the lifetime instead of the etch time corresponding to the lifetime.

Hereinafter, a detailed description is given of a method for determining the etching temperature corresponding to the lifetime in using the cleaning apparatus of Embodiment 5.

In order to determine a desired etching temperature, a BHF solution (containing 0.10% HF and 39.0% NH₄F) is fed into the cleaning apparatus as the cleaning solution. The temperature of the BHF solution is controlled by the electronic thermoregulator provided on the circulation line.

Under the above-described conditions, a target substrate is then immersed in the BHF solution contained in the inner treatment bath for certain etch time (3 minutes) to etch a target film (thermal oxide film) on the target substrate.

By measuring the etch amounts of the thermal oxide film corresponding to different etching temperatures, correlation between etching temperature and etch amount with respect to different lifetimes (0, 24 and 48 hours) is evaluated. Hereinafter, referring to Table 6, an explanation of the correlation between etching temperature and etch amount is provided.

Table 6 shows the etch amounts of the target film corresponding to the etching temperatures and the lifetimes (0, 24, and 48 hours).

As shown in Table 6, with the temperature of the BHF solution controlled at a certain etching temperature (21° C.) by the electronic thermoregulator, 4.0 nm of the thermal oxide film is etched when the lifetime of the BHF solution is 0 hour. On the other hand, 5.6 nm of the thermal oxide film is etched when the lifetime of the BHF solution is 24 hours.

TABLE 6

| Etching | Lifetime (h) | | |
|---|---|---|---|
| temperature | 0 h | 24 h | 48 h |
| (° C.) | Etch amount (nm) | Etch amount (nm) | Etch amount (nm) |
| 15.0 | 2.5 | 3.5 | 4.5 |
| 16.6 | 2.8 | 4.0 | 5.1 |
| 17.0 | 2.9 | 4.1 | 5.8 |
| 19.0 | 3.5 | 4.9 | 6.2 |
| 21.0 | 4.0 | 5.6 | 7.2 |
| 23.0 | 4.7 | 6.6 | 8.5 |

It is generally known that the etch amount of the target film depends on the etching temperature and can be represented by the Arrhenius' equation.

Therefore, irrespective of a change in lifetime (0, 24 or 48 hours), the amount of the thermal oxide film etched by the BHF solution increases at a certain rate with an increase in etching temperature as shown in Table 6.

For example, when the lifetime of the BHF solution is 24 hours, the etch amounts (3.5, 4.0, 4.1, 4.9, 5.6 and 6.6 nm) corresponding to the etching temperatures (15.0, 16.6, 17.0, 19.0, 21.0, and 23.0° C.) are measured. Thus, the etch amount increases at a certain rate with an increase in etching temperature.

Therefore, when the lifetime of the BHF solution is 24 hours, the temperature of the BHF solution is adjusted from 21° C. to 16.6° C. as shown in Table 6 such that the etch amount of the thermal oxide film is surely fixed to 4.0 nm.

In order to adjust the etching temperature as described above, the cleaning apparatus of Embodiment 5 is provided with the control unit or the CIM system which determines suitable etching temperature corresponding to the lifetime of the cleaning solution used.

For example, the control unit or the CIM system determines the etching temperature of 21° C. when the lifetime of the BHF solution is 0 hour, or the etching temperature of 16.6° C. when the lifetime of the BHF solution is 24 hours.

As shown in FIGS. 5A, 5B, 7A and 7B, the target substrate is immersed for certain etch time in the BHF solution which is contained in the inner treatment bath and controlled at a certain etching temperature by the control unit or the CIM system, thereby etching the target film on the target substrate.

As described above, the cleaning apparatus of Embodiment 5 of the present invention is provided with the control unit or the CIM system which determines a suitable etching temperature corresponding to the lifetime of the cleaning solution. Further, in the inner treatment bath of the cleaning apparatus of Embodiment 5, the target film is etched for certain etch time at the desired etching temperature determined by the control unit or the CIM system.

Therefore, even if the composition of the cleaning solution varies with a change in lifetime, the etch rate of the target film is not changed. Since the control unit or the CIM system controls the etching temperature based on the lifetime of the cleaning solution, the target film is etched under the suitable etching condition corresponding to the lifetime. This prevents the etch amount of the target film from varying with the change in lifetime. Therefore, the etch amount of the target film is fixed with reliability regardless of the lifetime.

Further, unlike the conventional examples, there is no need of replacing the cleaning solution flowing through the circulation line every time after a certain period has elapsed since the cleaning solution was fed into the circulation line. Therefore, replacement of the cleaning solution is carried out less frequently. As a result, the amount of the cleaning solution used is reduced and the operating rate of the cleaning apparatus improves, thereby leading to reduction in cost of manufacturing electronic devices.

### EMBODIMENT 6

Hereinafter, an explanation of a cleaning apparatus according to Embodiment 6 of the present invention is provided.

The cleaning apparatus of Embodiment 6 is composed of the batch-type cleaning apparatus of the first conventional example and a control unit 14 added thereto like the cleaning apparatus 10 of Embodiment 1. Or alternatively, the cleaning apparatus of Embodiment 6 is composed of the batch-type cleaning apparatus of the first conventional example and a CIM system 34 connected thereto via the control unit 14 like the cleaning apparatus 10 of Embodiment 2.

Therefore, in this embodiment, an explanation of the details of the cleaning apparatus already described in Embodiments 1 and 2 is omitted.

The control unit or the CIM system of the cleaning apparatus of Embodiment 6 determines etching temperature corresponding to the lifetime instead of the etch time corresponding to the lifetime.

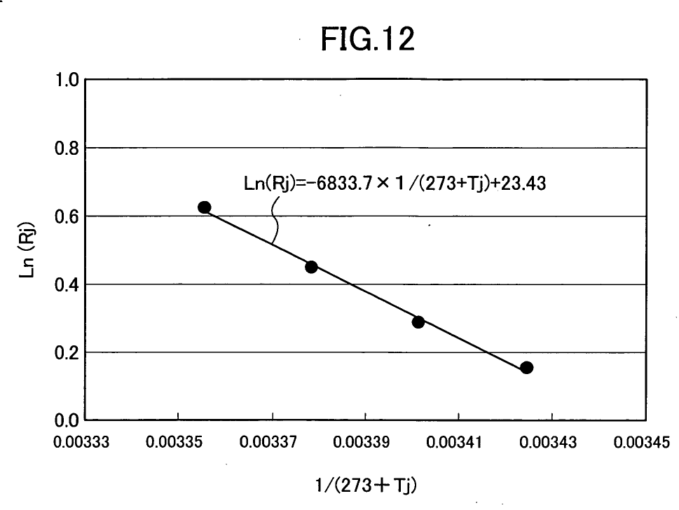

Hereinafter, with reference to Table 7 and FIG. 12, an explanation is given of a correction formula for determining the etching temperature corresponding to the lifetime of the cleaning solution in using the cleaning apparatus of Embodiment 6.

Table 7 shows the etch rates of the target film corresponding to different etching temperatures when the lifetime is 0 minute in the cleaning apparatus of Embodiment 6.

FIG. 12 is a graph illustrating correlation between 1/(273+Tj) and Ln(Rj) found when the cleaning apparatus of Embodiment 6 is used.

In this embodiment, the same explanation of the correction formula as described in Embodiment 3 is omitted.

In order to derive the correction formula for the cleaning apparatus of this embodiment, a target substrate is immersed in a BHF solution (containing 0.10% HF and 39.0% NH₄F) which is controlled at a certain temperature (etching temperature) by the electronic thermoregulator and contained in the inner treatment bath for certain etch time (180 seconds), thereby etching a target film (thermal oxide film) on the target substrate.

First, under the above-described conditions, an increase coefficient (B) of the etch rate of the thermal oxide film is obtained. As described above, the increase coefficient (B) of the etch rate of the thermal oxide film is obtained from the approximate equation [a]. The etch rate at which the BHF solution etches the thermal oxide film increases by 0.0004 (nm/min) per lifetime (min).
Increase coefficient (B)=0.0004 (nm/min²)

Then, under the above-described conditions, the etch rate (A) of the thermal oxide film when the lifetime of the BHF solution is 0 minute is obtained.

As described above, the etch rate (A) of the thermal oxide film is obtained from the approximate equation [b]. The amount of the thermal oxide film etched by the BHF solution just fed into the circulation line 20 (lifetime is 0 minute) increases by 1.2 (nm) per etch time (min).
Etch rate (A)=1.2 (nm/min)

Where the increase coefficient (B) and the etch rate (A) are thus obtained and the etch rate of the thermal oxide film when the lifetime of the BHF solution is Xi (minute) is defined as Yi (nm/min), the etch rate Yi of the thermal oxide film is obtained by the following formula [i].
Yi=0.0004Xi+1.2 [i]

Since the composition of the BHF solution varies with an increase in lifetime, the etch rate Yi (nm/min) of the thermal oxide film increases with an increase in lifetime Xi (min).

Then, as shown in Table 7, the etch rate Rj of the thermal oxide film etched by the BHF solution which has spent 0-minute lifetime is measured while the etching temperature Ti is varied (15, 17, 19, 21 and 23° C.). By so doing, correlation between the etching temperature Tj and the etch rate Rj is evaluated.

TABLE 7

| Etching temperature | | Etch rate Rj | |
|---|---|---|---|
| Tj (° C.) | 1/(273 + Tj) (1/K) | (nm/min) | Ln (Rj) |
| 15.0 | 0.00347 | −0.1831 | 0.83 |
| 17.0 | 0.00345 | −0.0195 | 0.98 |
| 19.0 | 0.00342 | 0.1542 | 1.17 |
| 21.0 | 0.00340 | 0.2877 | 1.33 |
| 23.0 | 0.00338 | 0.4490 | 1.57 |

As described above, it is generally known that the relationship between reaction rate and reaction temperature of a chemical reaction satisfies the Arrhenius' equation. Since the etch rate Rj is a reaction rate for an etching reaction, the relationship between the etch rate Rj and the etching temperature Tj (reaction temperature) is represented by the following formula [j] based on the Arrhenius' equation.
Ln(Rj)=−Ea/R×1/(273+Tj)+InA [j]

In this formula [j], R is a gas constant and Ea and A are eigenvalues. Specifically, Ea represents free energy of activation and A is a frequency factor.

Next, in order to obtain the eigenvalues Ea and A of the formula [j], the etch rates Rj corresponding to the etching temperatures Tj are substituted into the formula [j].

Specifically, the Ln(Rj) values corresponding to 1/(273+Tj) indicated in Table 7 are plotted as shown in FIG. 12 to obtain the eigenvalues Ea and A.

Then, specific values of R, Ea and A are substituted into the formula [j] to obtain the following formula [k].
Ln(Rj)=−6833.7×1/(273+Tj)+23.43 [k]

From the formula [k], the etch rate Rj is obtained by the formula [1].
Rj=e^{t} [1]
(wherein t=−6833.7×1/(273+Tj)+23.43)

Thus, as represented by the formula [i], the composition of the cleaning solution varies with an increase in lifetime. As a result, the etch rate of the target film also increases.

Therefore, in order to fix the etch rate (1.2 nm/min) regardless of the lifetime, it is necessary to determine the etching temperature based on variations in etch rate corresponding to variations in lifetime. Thus, the following formula [m] is derived.
Etch rate (A)×[Etch rate (A)/Etch rate Yi]=Etch rate Rj=e^{t} [m]
(wherein t=−6833.7×1/(273+Tj)+23.43)

By obtaining the etching temperature Tj (° C.) from the formula [m], the following formula [3] is derived. From the formula [3], the etching temperature corresponding to the lifetime Xi (min) is obtained.
Etching temperature Tj=6833.7/{23.43−Ln[Etch rate (A)×(Etch rate (A)/Etch rate Yi)]}−273 [3]

In this formula, the etch rate (A) is a value indicating the rate at which the amount of the target film etched by the cleaning solution just fed into the circulation line (cleaning solution circulation line) increases with an increase in etch time. For example, the etch rate (A) may be 1.2 (nm/min).

The etch rate Yi (nm/min) is a value indicating the rate at which the target film is etched by the cleaning solution for time Xi (min) elapsed since the cleaning solution was fed into the circulation line (cleaning solution circulation line).

For example, using the formula [3], the etching temperature Tj (° C.) corresponding to the lifetime Xi (min) under the above-described conditions may be obtained by the following formula [30].
Tj=6833.7/{23.43−Ln[1.44/(1.2+0.0004Xi)]}−273 [30]

From the formula [30], the etching temperature of 21° C. is determined when the lifetime of the BHF solution is 0 minute, while 16.6° C. is determined when the lifetime of the BHF solution is 1440 minutes.

In the control unit or the CIM system of the cleaning apparatus of Embodiment 6, the formula [3] is set as a correction formula and the etching temperature corresponding to the lifetime is obtained based on the formula [3].

For example, using the formula [3], the control unit or the CIM system determines the etching temperature of 21° C. when the lifetime of the BHF solution is 0 minute, or the etching temperature of 16.6° C. when the lifetime of the BHF solution is 1440 minutes.

As described above, the control unit or the CIM system of the cleaning apparatus of Embodiment 6 determines the suitable etching temperature corresponding to the lifetime using the formula [3] as shown in FIG. 5A or 5B and FIG. 7A or 7B. Further, in the inner treatment bath of the cleaning apparatus of this embodiment, the target film is subjected to etching at the desired etching temperature determined by the control unit or the CIM system for certain etch time.

Therefore, even if the composition of the cleaning solution varies with a change in lifetime, the etch rate of the target film is not changed. Since the control unit or the CIM system controls the etching temperature based on the lifetime of the cleaning solution, the target film is etched under the suitable etching condition corresponding to the lifetime. This prevents the etch amount of the target film from varying with the change in lifetime. Therefore, the etch amount of the target film is fixed with reliability regardless of the lifetime.

Further, unlike the conventional examples, there is no need of replacing the cleaning solution in the circulation line every time every time after a certain period of time has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 7

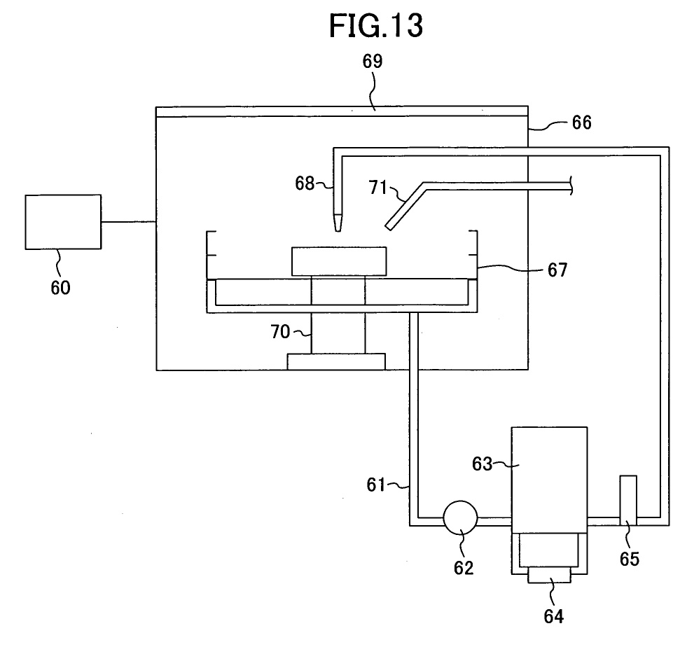

Hereinafter, with reference to FIG. 13, an explanation of the structure of a cleaning apparatus for electronic devices according to Embodiment 7 of the present invention is provided.

FIG. 13 is a sectional view illustrating the structure of the cleaning apparatus of Embodiment 7.

As shown in FIG. 13, the cleaning apparatus of this embodiment includes a circulation part, a cleaning part, a rinsing part and a control unit 60. Specifically, the cleaning apparatus is a combination of the single-wafer cleaning apparatus according to the first conventional example and the control unit 60.

The circulation part includes a circulation line (cleaning solution circulation line) 61, a circulation pump 62, a circulation tank 63, an electronic thermoregulator 64 and a filter 65 and a cleaning solution is circulated therein. The cleaning part includes a cleaning chamber 66, a cup 67, a cleaning solution nozzle 68, a HEPA 69 and a holder 70 and a target substrate is cleaned using the cleaning solution in the cleaning part. The rinsing part is adapted to rinse the target substrate with water and includes a rinsing nozzle 71.

Hereinafter, referring to FIG. 13, an explanation of a method for cleaning electronic devices using the cleaning apparatus of Embodiment 7 is provided.

First, a cleaning solution is fed into the circulation line 61 of the circulation part. The temperature of the cleaning solution fed into the circulation line 61 is adjusted by the electronic thermoregulator 64 provided on the circulation line 61. The cleaning solution whose temperature (etching temperature) has been controlled by the electronic thermoregulator 64 is fed from the circulation line 61 into the cleaning chamber 66 through the cleaning solution nozzle 68.

In the cleaning chamber 66, while the target substrate is being rotated by the holder 70 at predetermined revolutions, the cleaning solution is fed onto the target substrate supported by the holder 70 for desired etch time to etch the target film on the target substrate. The cleaning solution used for etching the target substrate is circulated along the circulation line 61 and reused in the cleaning chamber 66.

A condition for etching the target film (e.g., etch time) is controlled by the control unit 60 provided in the cleaning apparatus of this embodiment. Specifically, the control unit 60 measures the sum of durations spent for etching the target film since the cleaning solution was fed into the circulation line 61 (hereinafter the sum is referred to cumulative time) and determines suitable etch time corresponding to the measured cumulative time. Thus, suitable etching condition corresponding to the cumulative time is determined.

In this way, the control unit 60 determines the desired etch time corresponding to the cumulative time. Then, while the target substrate is being rotated by the holder 70, the cleaning solution is fed onto the target substrate for the desired etch time to etch the target film on the target substrate.

Then, in the rinsing part, the target substrate which has been subjected to etching in the cleaning part is rinsed with water using the rinsing nozzle 71. By so doing, the cleaning solution remaining on the target substrate is removed and at the same time, residues of the target film are etched by the remaining solution. That is, the target film is etched not only by the cleaning solution in the cleaning part but also by the remainder of the cleaning solution in the rinsing part.

Then, in the drying part (not shown), the target substrate rinsed in the rinsing part is dried.

Hereinafter, a detailed explanation is given of evaluations of correlation between cumulative time and etch amount and correlation between etch time and etch amount to determine the etch time corresponding to the cumulative time of the cleaning solution in the cleaning apparatus of Embodiment 7.

In order to evaluate the correlations, a polymer solution (containing 0.5% NH₄F, 45% organic solvent and 54.5% water) is used as the cleaning solution to be fed into the circulation line 61 of the cleaning apparatus of Embodiment 7. The polymer solution is controlled at a certain etching temperature (e.g., 25° C.) by the electronic thermoregulator 64 provided on the circulation line 61.

First, for the evaluation of the correlation between cumulative time and etch amount under the above-described conditions, the polymer solution is fed from the cleaning solution nozzle 68 onto the target substrate which is supported on and being rotated by the holder 70 for certain etch time (e.g., 3 minutes) to etch the target film (plasma TEOS film) on the target substrate.

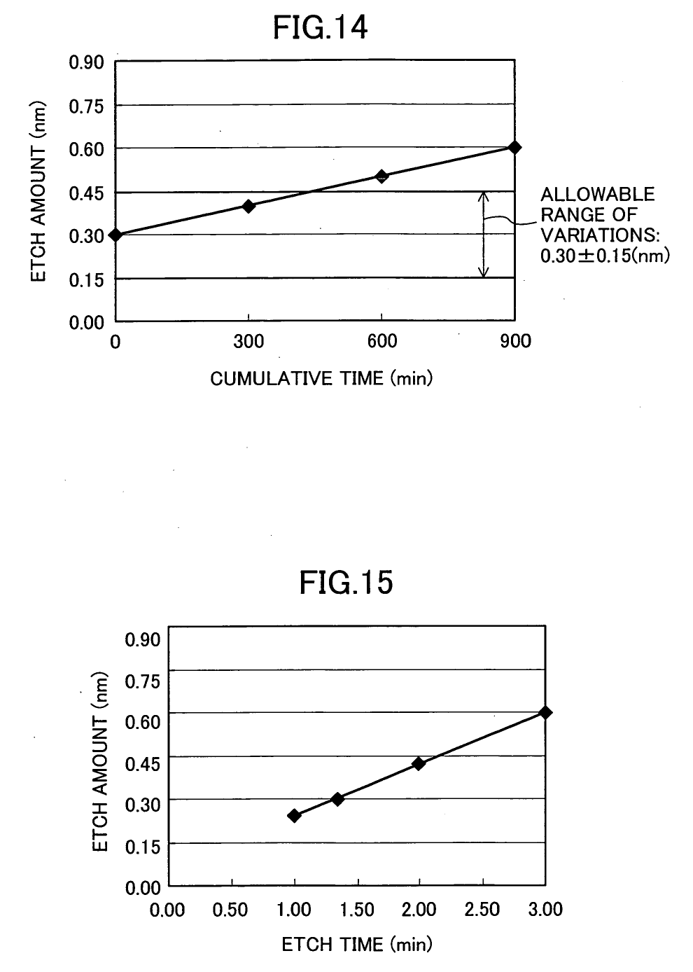

By measuring the amounts of the plasma TEOS film corresponding to different cumulative times, the correlation between cumulative time and etch amount is evaluated. Hereinafter, referring to Table 8 and FIG. 14, an explanation of the correlation between cumulative time and etch amount found when the cleaning apparatus of Embodiment 7 is used is provided.

Table 8 shows the etch amounts of the target film corresponding to the cumulative times when the cleaning apparatus of Embodiment 7 is used.

FIG. 14 is a graph illustrating the correlation between cumulative time and etch amount found when the cleaning apparatus of Embodiment 7 is used.

As shown in Table 8, the amounts of the plasma TEOS film etched by the polymer solution are measured after different cumulative times (0, 300, 600 and 900 minutes) have elapsed.

TABLE 8

| Number of | Cumulative | Etch |
|---|---|---|
| substrates treated | time (min) | amount (nm) |
| 0 | 0 | 0.3 |
| 100 | 300 | 0.4 |
| 200 | 600 | 0.5 |
| 300 | 900 | 0.6 |

As described above, the cumulative time is the sum of durations spent for etching the target film since the cleaning solution was fed into the circulation line 61. Specifically, the 1^{st} target substrate will be etched by the cleaning solution which has not spent any cumulative time (0 minute) since the cleaning solution was fed into the circulation line 61. Further, the 101^{st} target substrate will be etched by the cleaning solution which has spent 300-minute cumulative time, the 201^{st} target substrate will be etched by the cleaning solution which has spent 600-minute cumulative time, and the 301^{st} target substrate will be etched by the cleaning solution which has spent 900-minute cumulative time.

That is, as shown in Table 8, when the cumulative time is 0 minute, no target substrate has been treated by the cleaning solution. Further, 100 target substrates have been treated when the cumulative time reached 300 minutes, 200 target substrates have been treated when the cumulative time reached 600 minutes and 300 target substrates have been treated when the cumulative time reached 900 minutes.

Then, the measured etch amounts of the plasma TEOS film corresponding to the cumulative times are plotted as shown in FIG. 14 to evaluate the correlation between cumulative time and etch amount.

FIG. 14 shows that the etch amount of the plasma TEOS film increases at a certain rate with an increase in cumulative time. Specifically, 0.3 nm of the plasma TEOS film is etched by the polymer solution which has spent the cumulative time of 0 minute. On the other hand, 0.6 nm of the plasma TEOS film is etched by the polymer solution which has spent 900-minute cumulative time. The results indicate that the polymer solution which has spent 900-minute cumulative time etches a larger amount of the plasma TEOS film than the polymer solution which has spent 0-minute cumulative time.

Now, a cause of the increase in etch amount of the plasma TEOS film with an increase in cumulative time is described below.

The polymer solution is dissociated into NH₃, NH₄⁺ and HF₂⁻ and equilibrated in this state. Therefore, the polymer solution contains NH₄F, NH₃, NH₄⁺ and HF₂⁻.

Among them, NH₃ has a lower vapor pressure than the other components (NH₄F, NH₄⁺ and HF₂⁻) and therefore is likely to evaporate. Since the polymer solution is fed from the cleaning solution nozzle 68 onto the target substrate in the form of a fine mist, NH₃ selectively evaporates from the polymer solution. Therefore, NH₃ evaporates to decrease the NH₃ concentration in the polymer solution with an increase in cumulative time.

As a result, the equilibrium of the polymer solution is shifted to the right (toward the system of formation) and a larger amount of HF₂⁻ is dissociated as shown in the equation (II). Accordingly, the concentration of HF₂⁻ as an etchant increases in the polymer solution.
2NH₄F→NH₃↑+HH₄⁺+HF₂⁻ (II)

Since the HF₂⁻ concentration in the polymer solution increases with an increase in cumulative time, the etch amount of the plasma TEOS film also increases.

Specifically, as compared with a polymer solution which has spent 0-minute cumulative time, the polymer solution which has spent the cumulative time of 900 minutes varies the composition thereof, i.e., the HF₂⁻ concentration increases. Therefore, the polymer solution which has spent 900-minute cumulative time etches a larger amount of the plasma TEOS film (0.6 nm) than the polymer solution which has spent 0-minute cumulative time (0.3 nm).

Thus, from the evaluation of the correlation between cumulative time and etch amount found when the cleaning apparatus of Embodiment 7 is used, it is indicated that the etch amount of the target film increases at a certain rate with an increase in cumulative time.

Now, for the evaluation of the correlation between etch time and etch amount under the above-described conditions, the polymer solution which has spent optionally selected cumulative time (e.g., 900 minutes) is fed from the cleaning solution nozzle 68 onto the target substrate which is supported on and being rotated by the holder 70 to etch the target film (plasma TEOS film) on the target substrate.

By measuring the amounts of the plasma TEOS film etched for different etch times, the correlation between etch time and etch amount when the polymer solution which has spent 900-minute cumulative time is used is evaluated. Hereinafter, referring to Table 9 and FIG. 15, an explanation of the correlation between etch time and etch amount found when the cleaning apparatus of Embodiment 7 is used is provided.

Table 9 shows the etch amounts of the target film corresponding to different etch times when the cleaning apparatus of Embodiment 7 of the present invention is used.

FIG. 15 is a graph illustrating the correlation between etch time and etch amount found when the cleaning apparatus of Embodiment 7 of the present invention is used.

As shown in Table 9, the amounts of the plasma TEOS film etched by the polymer solution for different etch times (180, 120, 80 and 60 seconds) are measured. Then, the etch amounts of the plasma TEOS film corresponding to the etch times are plotted as shown in FIG. 15 to evaluate the correlation between etch time and etch amount.

TABLE 9

| Etch time (min) | Etch time (s) | Etch amount (nm) |
|---|---|---|
| 3.00 | 180 | 0.60 |
| 2.00 | 120 | 0.42 |
| 1.33 | 80 | 0.30 |
| 1.00 | 60 | 0.24 |

FIG. 15 indicates that the etch amount of the plasma TEOS film decreases at a certain rate with a decrease in etch time. Specifically, 0.60 nm of the plasma TEOS film is etched when the etch time is 180 seconds, while 0.30 nm of the plasma TEOS film is etched when the etch time is 80 seconds.

As shown in Table 8 and FIG. 14, where the etch time is fixed (180 seconds) irrespective of the cumulative time, 0.3 nm of the plasma TEOS film is etched by the polymer solution which has spent 0-minute cumulative time, while 0.6 nm of the plasma TEOS film is etched by the polymer solution which has spent 900-minute cumulative time. In this case, if the allowable range of variations in etch amount of the plasma TEOS film is ±50%, i.e., 0.30±0.15 (nm) as shown in FIG. 14, the amount etched by the polymer solution which has spent 900-minute cumulative time deviates from the allowable range.

Therefore, as shown in Table 9 and FIG. 15, if the etch time is changed from 180 seconds to 80 seconds when the polymer solution has spent 900-minute cumulative time, the etch amount of the plasma TEOS film is surely controlled to 0.3 nm, which is the same etch amount when the cumulative time is 0 minute.

In order to adjust the etch time as described above, the cleaning apparatus of Embodiment 7 is provided with the control unit 60 which determines the etch time corresponding to the cumulative time of the cleaning solution.

For example, as shown in Tables 8 and 9 and FIGS. 14 and 15, the control unit 60 determines the etch time of 180 seconds when the cumulative time of the polymer solution is 0 minute. On the other hand, the control unit 60 determines the etch time of 80 seconds when the cumulative time of the polymer solution is 900 minutes.

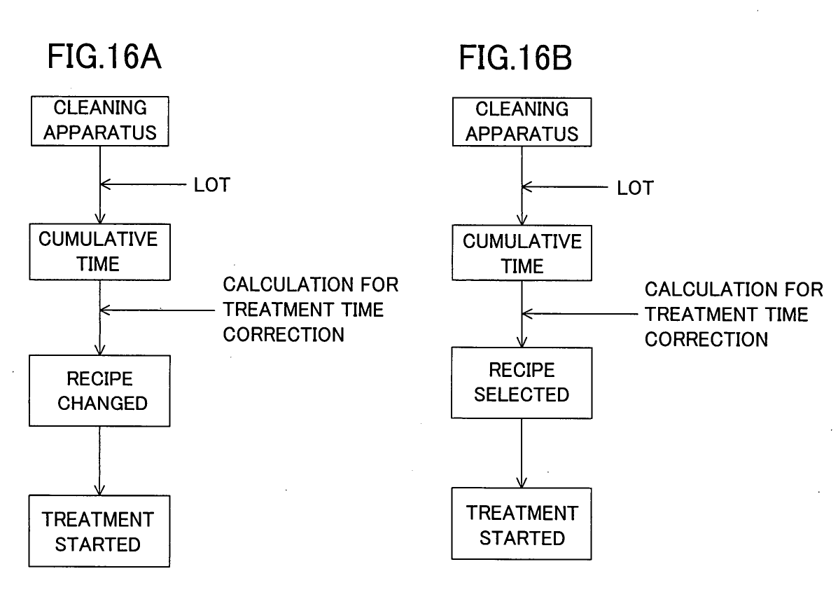

Hereinafter, referring to FIGS. 16A and 16B, an explanation of processing flows in the control unit 60 provided in the cleaning apparatus of Embodiment 7 is provided.

FIGS. 16A and 16B are diagrams illustrating processing flows in the control unit 60 provided in the cleaning apparatus of Embodiment 7.

As shown in FIG. 16A, in lot processing, the control unit 60 first reads out the sum of durations spent for etching the target film since the cleaning solution was fed into the circulation line 61, i.e., cumulative time. Then, the control unit 60 determines an etching condition corresponding to the read-out cumulative time, i.e., etch time, using a correction formula. Subsequently, the control unit 60 rewrites an etch time preset in a recipe (processing instructions) of the control unit 60 as the determined desired etch time.

In this way, the control unit 60 changes the etch time previously set in the recipe into the desired etch time corresponding to the cumulative time.

Then, in the cleaning chamber 66, while the target substrate is being rotated by the holder 70, the cleaning solution is fed onto the target substrate for the desired etch time to etch the target film on the target substrate.

For example, as described above, when the cumulative time of the polymer solution is 0 minute, the etch time preset in the recipe is rewritten as 180 seconds. On the other hand, when the cumulative time of the polymer solution is 900 minutes, the preset etch time is rewritten as 80 seconds. As a result, the plasma TEOS film is subjected to etching for certain etch time corresponding to the cumulative time of the polymer solution. Thus, the etch amount of the plasma TEOS film is fixed (0.3 nm) with reliability regardless of the cumulative time.

Further, as shown in FIG. 16B, in lot processing, the control unit 60 first reads out the sum of durations spent for etching the target film since the cleaning solution was fed into the circulation line 61, i.e., cumulative time. Then, the control unit 60 determines an etching condition corresponding to the read-out cumulative time, i.e., etch time, using a correction formula. Subsequently, based on the determined etch time, the control unit 60 selects a desired etch time from a plurality of etch times preset in a recipe (processing instructions) of the control unit 60.

In this way, the control unit 60 selects the desired etch time corresponding to the cumulative time from the plurality of etch times previously stored in the recipe.

Then, in the cleaning chamber 66, the cleaning solution is fed onto the target substrate being rotated by the holder 70 for the desired etch time to etch the target film on the target substrate.

For example, when the cumulative time of the polymer solution is 0 minute, the etch time of 180 seconds is selected from the plurality of etch times set in the recipe. On the other hand, when the cumulative time of the polymer solution is 900 minutes, the etch time of 80 seconds is selected from the plurality of etch times set in the recipe. By so doing, the plasma TEOS film is etched for the etch time corresponding to the cumulative time of the polymer solution. As a result, the etch amount of the plasma TEOS film is fixed (0.3 nm) with reliability regardless of the cumulative time.

As described above, the cleaning apparatus of Embodiment 7 of the present invention is provided with the control unit 60 which determines the etch time corresponding to the cumulative time of the cleaning solution as shown in FIG. 16A or 16B. Further, in the cleaning chamber 66 of the cleaning apparatus of Embodiment 7, the target film is etched for the desired etch time determined by the control unit 60.

Therefore, even if the composition of the cleaning solution varies with a change in cumulative time and the etch rate of the target film is changed, the control unit 60 controls the etch time based on the cumulative time of the cleaning solution used. As a result, the target film is etched under the suitable etching condition corresponding to the cumulative time. That is, the etch amount of the target film is prevented from varying with the change in cumulative time. Therefore, the etch amount of the target film is fixed with reliability regardless of the cumulative time.

Further, unlike the conventional examples, there is no need of replacing the cleaning solution in the circulation line every time after a certain period of time has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 8

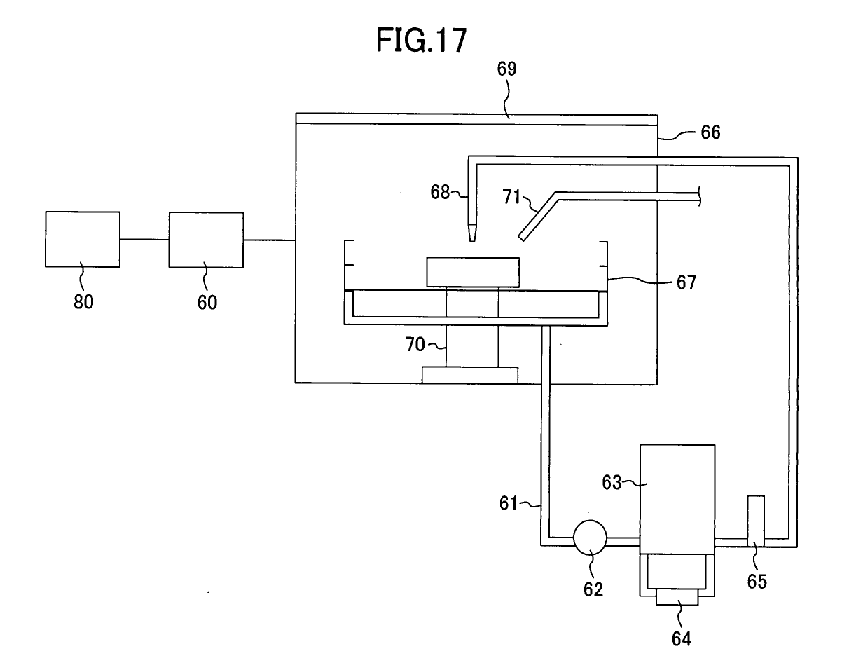

Hereinafter, with reference to FIG. 17, an explanation of the structure of a cleaning apparatus for electronic devices according to Embodiment 8 of the present invention is provided.

FIG. 17 is a sectional view illustrating the structure of the cleaning apparatus of Embodiment 8 of the present invention.

In FIG. 17, the same components as those of the cleaning apparatus described in Embodiment 7 are indicated by the same reference numerals. Therefore, in this embodiment, explanation of the components already detailed in Embodiment 7 is omitted.

As shown in FIG. 17, the cleaning apparatus of this embodiment includes a circulation part, a cleaning part, a rinsing part and a control unit 60. Further, a CIM system (Computer Integrated Manufacturing) system 80 is connected to the cleaning apparatus via the control unit 60. That is, the cleaning apparatus of this embodiment is a combination of the single-wafer cleaning apparatus according to the first conventional example and the CIM system 80 connected thereto via the control unit 60.

Hereinafter, with reference to Tables 8 and 9 and FIGS. 14 and 15, a brief explanation of a method for determining the etch time corresponding to the cumulative time of a cleaning solution in the cleaning apparatus of Embodiment 8 is provided.

As shown in Tables 8 and 9 and FIGS. 14 and 15, with use of the cleaning apparatus of Embodiment 8, an intended amount (0.3 nm) of the plasma TEOS film is surely etched in 180 seconds when the cumulative time of the polymer solution is 0 hour. On the other hand, when the cumulative time of the polymer solution is 24 hours, the intended amount (0.3 nm) of the plasma TEOS film is surely etched in 80 seconds.

In order to adjust the etch time as described above, the cleaning apparatus of Embodiment 8 is provided with the CIM system 80 connected thereto via the control unit 60. The CIM system 80 determines suitable etch time corresponding to the cumulative time of the cleaning solution.

For example, as shown in Tables 8 and 9 and FIGS. 14 and 15, when the cumulative time of the polymer solution is 0 hour, the CIM system 80 determines the etch time of 180 seconds. On the other hand, when the cumulative time of the polymer solution is 24 hours, the CIM system 80 determines the etch time of 80 seconds.

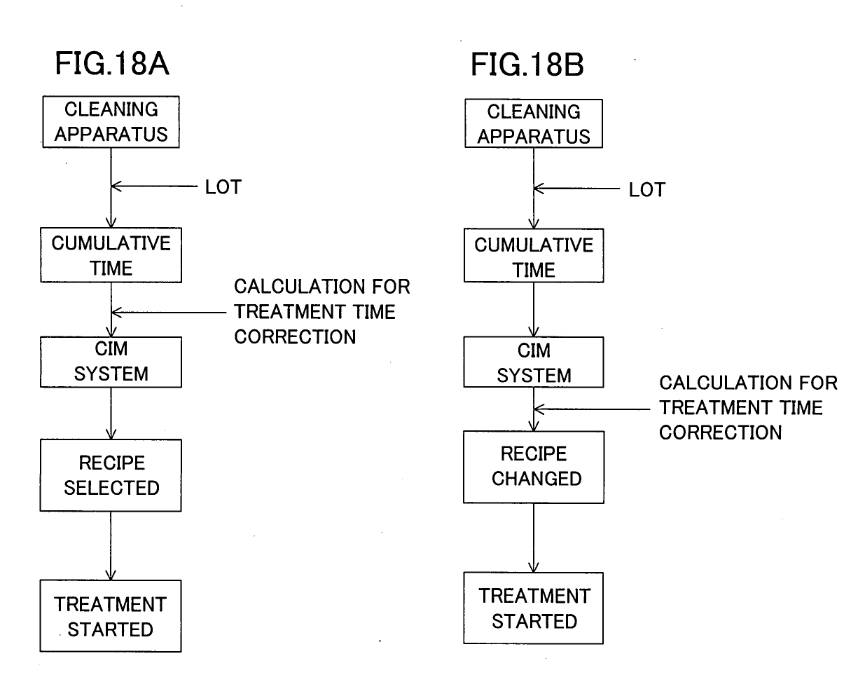

Hereinafter, with reference to FIGS. 18A and 18B, an explanation of processing flows in the CIM system 80 connected to the cleaning apparatus of Embodiment 8 is provided.

FIGS. 18A and 18B are diagrams illustrating processing flows in the CIM system 80 connected to the cleaning apparatus of Embodiment 8.

As shown in FIG. 18A, first, in lot processing, the control unit 60 first reads out the sum of durations spent for etching the target film since the cleaning solution was fed into the circulation line 61, i.e., cumulative time. Then, upon receipt of the cumulative time data from the control unit 60, the CIM system 80 determines the etching condition corresponding to the read-out cumulative time, i.e., etch time, using a correction formula. Subsequently, based on the determined etch time, the CIM system 80 selects suitable etch time from a plurality of etch times preset in a recipe (processing instructions) of the control unit 60.

In this way, the control unit 60 selects the desired etch time corresponding to the cumulative time from the plurality of etch times previously stored in the recipe of the control unit 60.

Then, in the cleaning chamber 66, the cleaning solution is fed onto the target substrate which is being rotated by the holder 70 to etch the target film on the target substrate.

Further, as shown in FIG. 18B, first, in lot processing, the control unit 60 first reads out the sum of durations spent for etching the target film since the cleaning solution was fed into the circulation line 61, i.e., cumulative time. Then, upon receipt of the cumulative time data from the control unit 60, the CIM system 80 determines the etching condition corresponding to the read-out cumulative time, i.e., etch time, using a correction formula. Subsequently, the CIM system 80 rewrites an etch time preset in a recipe (processing instructions) of the control unit 60 as the determined desired etch time.

In this way, the control unit 60 changes the etch time previously stored in the recipe into the desired etch time corresponding to the cumulative time.

Then, in the cleaning chamber 66, the cleaning solution is fed onto the target substrate which is being rotated by the holder 70 to etch the target film on the target substrate.

As described above, the cleaning apparatus of Embodiment 8 of the present invention is provided with the control unit 60 and the CIM system 80 is connected to the system via the control unit 60. The CIM system 80 determines the etch time corresponding to the lifetime of the cleaning solution as shown in FIG. 18A or 18B. Further, in the cleaning chamber 66 of the cleaning apparatus, the target film is etched for the desired etch time determined by the CIM system 80.

Therefore, even if the composition of the cleaning solution varies with a change in cumulative time and the etch rate of the target film is changed, the CIM system 80 controls the etch time based on the cumulative time. As a result, the target film is etched under the suitable etching condition corresponding to the cumulative time, i.e., the etch amount of the target film is prevented from varying with the change in cumulative time. Therefore, the etch amount of the target film is fixed with reliability regardless of the cumulative time.

Further, unlike the conventional examples, there is no need of replacing the cleaning solution in the circulation line every time after a certain period has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 9

Hereinafter, an explanation of a cleaning apparatus for electronic devices according to Embodiment 9 of the present invention is provided.

The cleaning apparatus of Embodiment 9 is composed of the single-wafer cleaning apparatus of the first conventional example and a control unit 60 added thereto like the cleaning apparatus of Embodiment 7. Or alternatively, the cleaning apparatus of Embodiment 9 is composed of the single-wafer cleaning apparatus of the first conventional example and a CIM system 80 is connected thereto via the control unit 60 like the cleaning apparatus of Embodiment 7.

Therefore, in this embodiment, an explanation of the details of the cleaning apparatus already described in Embodiments 7 and 8 is omitted.

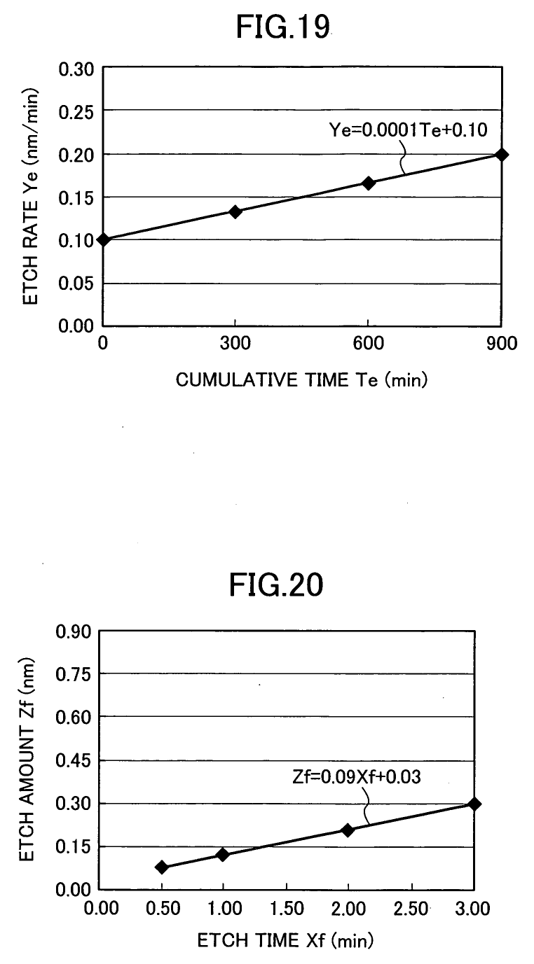

Hereinafter, with reference to Tables 10, 11 and 12 and FIGS. 19, 20 and 21, an explanation of a correction formula for determining the etch time corresponding to the cumulative time of the cleaning solution in the cleaning apparatus of Embodiment 9 is provided.

In order to derive the correction formula for the cleaning apparatus of this embodiment, a polymer solution (containing 0.5% NH₄F, 45% organic solvent and 54.5% water) which is controlled at a certain etching temperature (e.g., 25° C.) is fed from the cleaning solution nozzle 68 onto the target substrate supported on the holder 70 for certain etch time (e.g., 180 seconds), thereby etching a target film (plasma TEOS film) on the target substrate. At this time, the target substrate is being rotated by the holder 70 at predetermined revolutions.

First, under the above-described conditions, the following measurement is carried out to obtain an increase coefficient (F) of the etch rate of the plasma TEOS film.

The increase coefficient (F) is the rate at which the etch rate of the plasma TEOS film increases with an increase in cumulative time.

Table 10 shows the etch rates of the target film corresponding to different cumulative times in the cleaning apparatus of Embodiment 9.

FIG. 19 is a graph illustrating correlation between cumulative time and etch rate found when the cleaning apparatus of Embodiment 9 is used.

As shown in Table 10, measurement of the etch rate of the plasma TEOS film is carried out after different cumulative times (0, 300, 600 and 900 minutes) have elapsed. Then, the measured etch rates corresponding to the cumulative times are plotted as shown in FIG. 19 to evaluate the correlation between cumulative time and etch rate.

TABLE 10

| Cumulative time (min) | Etch amount (nm) | Etch rate (nm/min) |
|---|---|---|
| 0 | 0.3 | 0.10 |
| 300 | 0.4 | 0.13 |
| 600 | 0.5 | 0.17 |
| 900 | 0.6 | 0.20 |

Provided that the etch rate of the plasma TEOS film when the cumulative time is Te (min) is Ye (nm/min), a relationship between the cumulative time Te and the etch rate Ye of the plasma TEOS film is represented by a linear function. Therefore, the following approximate equation [e] is derived.
Ye=0.0001Te+0.10 [e]

From the approximate equation [e], the increase coefficient (F) of the etch rate of the plasma TEOS film is obtained. Thus, the rate at which the polymer solution etches the plasma TEOS film increases by 0.0001 (nm) per cumulative time (min).

In this way, the composition of the polymer solution varies with an increase in cumulative time, whereby the etch amount of the plasma TEOS film increases. As a result, the etch rate of the plasma TEOS film increases.

Then, under the above-described conditions, the following measurement is carried out to obtain the etch rate (E) of the plasma TEOS film and the additional etch amount (G) of the plasma TEOS film.

The etch rate (E) is the rate at which the amount of the plasma TEOS film etched by the polymer solution just fed into the circulation line increases with an increase in etch time.

The additional etch amount (G) is the amount of the plasma TEOS film additionally etched during the rinsing step by the remainder of the polymer solution just fed into the circulation line.

Table 11 shows the etch amounts of the target film corresponding to different etch times when the cleaning apparatus of Embodiment 9 is used and the cumulative time of the polymer solution is 0 minute.

FIG. 20 is a graph illustrating correlation between etch time and etch amount found when the cleaning apparatus of Embodiment 9 is used and the cumulative time of the polymer solution is 0 minute.

As shown in Table 11, the amounts of the plasma TEOS film etched by the polymer solution which has just fed into the circulation line, i.e., the cumulative time is 0 minute, for different etch times (0.5, 1, 2 and 3 minutes) are measured. Then, the etch amounts corresponding to the different etch times are plotted as shown in FIG. 20 to evaluate the correlation between etch time and etch amount found when the cumulative time of the polymer solution is 0 minute.

TABLE 11

| Etch time (min) | Etch time (s) | Etch amount (nm/min) |
|---|---|---|
| 0.50 | 30 | 0.08 |
| 1.00 | 60 | 0.12 |
| 2.00 | 120 | 0.21 |
| 3.00 | 180 | 0.30 |

Provided that the amount of the plasma TEOS film etched in the etch time Xf (min) is Zf (nm), a relationship between the etch time Xf and the etch amount Zf where the cumulative time is 0 minute is represented by a linear function. Therefore, the following approximate equation [f] is derived.
Zf=0.09Xf+0.03 [f]

From the approximate equation [f], the etch rate (E) of the plasma TEOS film is obtained. Thus, the amount of the plasma TEOS film etched by the polymer solution which has spent 0-minute cumulative time increases by 0.09 (nm) per etch time (min).

Further, from the approximate equation [f], the additional etch amount (G) of the plasma TEOS film is obtained. Thus, the amount of the plasma TEOS film additionally etched during the rinsing step by the remainder of the polymer solution which has spent 0-minute cumulative time is 0.03 (nm).

Then, under the above-described conditions, the following measurement is carried out to obtain the additional etch rate (H) of the plasma TEOS film.

The additional etch rate (H) is the rate at which the amount of the plasma TEOS film etched by the remainder of the polymer solution during the rinsing step (i.e., the additional etch amount of the plasma TEOS film) increases with an increase in cumulative time.

Table 12 shows the etch amounts of the target film corresponding to different etch times when the cleaning apparatus of Embodiment 9 is used and the cumulative time of the polymer solution is 900 minutes.

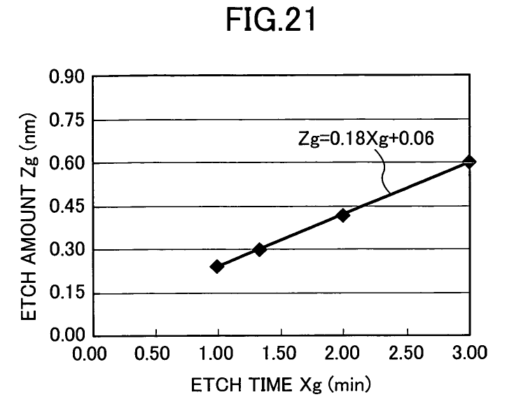

FIG. 21 is a graph illustrating correlation between etch time and etch amount found when the cleaning apparatus of Embodiment 9 is used and the cumulative time of the polymer solution is 900 minutes.

As shown in Table 12, the amounts of the plasma TEOS film etched by the polymer solution which has spent optionally selected cumulative time (e.g., 900 minutes) for different etch times (1, 2 and 3 minutes) are measured. Then, the measured etch amounts corresponding to the etch times are plotted as shown in FIG. 21 to evaluate the correlation between etch time and etch amount found when the cumulative time of the polymer solution is 900 minutes.

TABLE 12

| Etch time (min) | Etch time (s) | Etch amount (nm) |
|---|---|---|
| 1.00 | 60 | 0.24 |
| 1.33 | 80 | 0.30 |
| 2.00 | 120 | 0.42 |
| 3.00 | 180 | 0.60 |

Provided that the amount of the plasma TEOS film etched in the etch time Xg (min) is Zg (nm), a relationship between the etch time Xg and the etch amount Zg where the cumulative time is 900 minutes is represented by a linear function. Therefore, the following approximate equation [g] is derived.
Zg=0.18Xg+0.06 [g]

The approximate equation [g] shows that the amount of the plasma TEOS film etched during the rinsing step by the remainder of the polymer solution which has spent 900-minute cumulative time is 0.06 (nm).

Further, it is also indicated that the amount of the plasma TEOS film etched by the polymer solution which has spent 900-minute cumulative time increases by 0.18 (nm) per etch time (min).

The approximate equation [f] shows that the etch rate (E) of the plasma TEOS film when the cumulative time is 0 minute is 0.09 (nm/min), while the approximate equation [e] shows that the increase coefficient (F) of the plasma TEOS film is 0.0001 (nm/min²). Therefore, the etch rate of the plasma TEOS film when the cumulative time is 900 minutes may be obtained by the following formula:
0.09 (nm/min)+0.0001 (nm/min²)×900 (min)=0.18 (nm/min)

Since the composition of the polymer solution varies with an increase in cumulative time as described above, the amount of the plasma TEOS film etched by the polymer solution also increases. In a like manner, the amount of the plasma TEOS film etched by the remainder of the polymer solution (hereinafter referred to as the additional etch amount) also increases with an increase in cumulative time.

The approximate equation [f] of FIG. 20 shows that the additional etch amount of the plasma TEOS film when the cumulative time is 0 minute is 0.03 (nm), while the approximate equation [g] of FIG. 21 shows that the additional etch amount of the plasma TEOS film when the cumulative time is 900 minutes is 0.06 (nm). Thus, the additional etch amount of the plasma TEOS film increases with an increase in cumulative time.

Therefore, provided that the additional etch amount of the plasma TEOS film when the cumulative time is Th (min) is Wh (nm), the relationship between the cumulative time Th and the additional etch amount Wh is represented by a linear function. Thus, the following approximate equation [h] is derived.
Wh=(3.33×10⁻⁶)×Th+0.03 [h]

From the approximate equation [h], the additional etch rate (H) of the plasma TEOS film is obtained. Thus, the amount of the plasma TEOS film additionally etched by the remainder of the polymer solution during the rinsing step (the additional etch amount) increases by 3.33×10⁻⁶ (nm) per cumulative time (min).

From the approximate equations [e], [f] and [h], the etch time corresponding to the cumulative time is obtained using the following formula [2].
Etch time={Intended etch amount−[Additional etch amount (G)+Additional etch rate (H)×Cumulative time]}/{Etch rate (E)+Increase coefficient (F)×Cumulative time} [2]

In the formula [2], the increase coefficient (F) is a value indicating the rate at which the etch rate of the target film increases with an increase in cumulative time and obtained from the approximate equation [e]. For example, the increase coefficient (F) may be 0.0001 (nm/min²).

The etch rate (E) is a value indicating the rate at which the amount of the target film etched by the cleaning solution just fed into the circulation line (cleaning solution circulation path) increases with an increase in etch time and obtained from the approximate equation [f]. For example, the etch rate (E) may be 0.09 (nm/min).

The additional etch amount (G) is the amount of the target film additionally etched during the rinsing step by the remainder of the cleaning solution just fed into the circulation line and obtained from the approximate equation [f]. For example, the additional etch amount (G) may be 0.03 (nm).

The additional etch rate (H) is a value indicating the rate at which the additional etch amount of the target film increases with an increase in cumulative time and obtained from the approximate equation [h]. For example, the additional etch rate (H) may be 3.33×10⁻⁶ (nm/min²).

In the control unit 60 or the CIM system 80 of the cleaning apparatus of Embodiment 9, the formula [2] is set as a correction formula and suitable etch time corresponding to the cumulative time is determined based on the formula [2].

For example, as shown in Tables 8 and 9 and FIGS. 14 and 15, the control unit 60 or the CIM system 80 determines, using the formula [2], the etch time of 180 seconds when the cumulative time of the polymer solution is 0 minute, or the etch time of 120 seconds when the cumulative time of the polymer solution is 900 minutes.

As described above, the control unit or the CIM system of the cleaning apparatus of Embodiment 9 determines the etch time corresponding to the cumulative time using the formula [2] as shown in FIG. 16A or 16B and FIG. 18A or 18B. Then, in the cleaning chamber of the cleaning apparatus of this embodiment, the target film is subjected to etching for the desired etch time determined by the control unit or the CIM system.

Therefore, even if the composition of the cleaning solution varies with a change in cumulative time and the etch rate of the target film is changed, the control unit or the CIM system controls the etch time based on the cumulative time. As a result, the target film is etched under the suitable etching condition corresponding to the cumulative time, i.e., the etch amount of the target film is prevented from varying with the change in cumulative time. Therefore, the etch amount of the target film is fixed with reliability regardless of the cumulative time.

Further, unlike the conventional examples, there is no need of replacing the cleaning solution flowing through the circulation line every time after a certain period has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 10

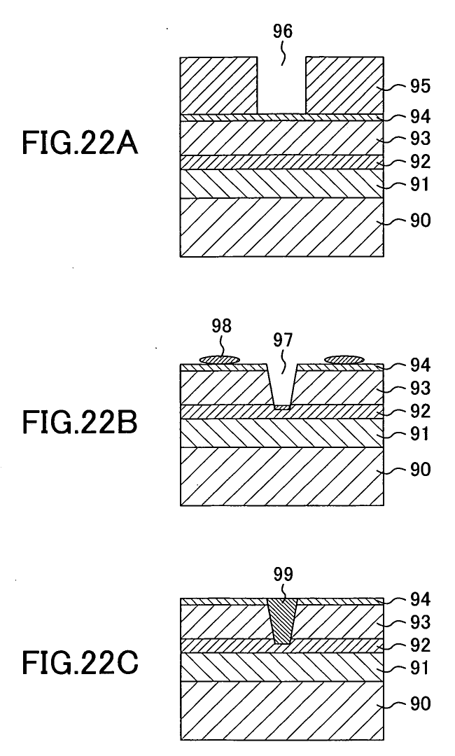

Hereinafter, with reference to FIGS. 22A to 22C, an explanation of a method for cleaning electronic devices using a cleaning apparatus according to Embodiment 10 of the present invention is provided.

FIGS. 22A to 22C are sectional views of a major part illustrating the steps of a method for cleaning the electronic devices according to Embodiment 10 of the present invention.

As shown in FIG. 22A, an oxide film 91, a plasma nitride film (SiN film) 92, a SiOC film 93 and a plasma TEOS film 94 are formed in this order on a silicon substrate 90. Then, a resist 95 applied onto the plasma TEOS film 94 is patterned into a desired shape, thereby forming an opening 96 which exposes part of the plasma TEOS film 94. Through the opening 96, the plasma TEOS film 94 and the SiOC film 93 are removed by dry etching, thereby forming a via hole 97 of a desired shape.

Then, after the dry etching, ashing is carried out with oxygen plasma to remove resist residues 98 shown in FIG. 22B. Then, the plasma TEOS film is further etched, thereby cleaning the resulting substrate and forming a via hole 97 having a desired diameter.

For example, as a cleaning solution for the cleaning apparatus of this embodiment, a polymer solution (containing 0.5% NH₄F, 45% organic solvent and 54.5% water) which is controlled at 25° C. is fed from a cleaning solution nozzle 68 onto the target substrate (silicon substrate 90) for certain etch time corresponding to the cumulative time of the solution. At this time, the target substrate 90 is supported on and being rotated by a holder 70. In this way, the target film (the plasma TEOS film 94) on the silicon substrate 90 is etched.

Specifically, as shown in Tables 8 and 9 and FIGS. 14 and 15, while the silicon substrate 90 is being rotated by the holder, the polymer solution is fed onto the silicon substrate 90 for 180 seconds when the cumulative time of the polymer solution is 0 minute. On the other hand, the polymer solution is fed onto the rotating silicon substrate 90 for 80 seconds when the cumulative time of the polymer solution is 900 minutes.

By etching the plasma TEOS film 94 with the polymer solution for the etch time corresponding to the cumulative time, the etch amount of the plasma TEOS film 94 is surely fixed to 0.3 nm.

Then, as shown in FIG. 22C, a copper film is formed on the plasma TEOS film 94 to fill the via hole 97. Then, the copper film is flattened by CMP to form a copper wire 99.

As described above, with use of the cleaning apparatus of Embodiment 10, the target film (plasma TEOS film 94) is etched for the etch time corresponding to the cumulative time of the cleaning solution. Since the etch amount is fixed (0.3 nm), the standard of the diameter of the via hole is satisfied irrespective of the cumulative time.

Therefore, even if the composition of the cleaning solution varies with an increase in cumulative time, the plasma TEOS film 94 is not etched too much. Therefore, the diameter of the via hole will not increase too much.

Since the plasma TEOS film 94 is not etched too much and the diameter of the via hole does not increase too much, adjacent via holes 97 will not come into contact with each other, thereby preventing product defects caused by the contact between adjacent contact holes 97. As a result, the yield of the electronic devices improves.

As described above, according to the cleaning apparatus of Embodiment 10, the target film is etched under suitable etching condition corresponding to the cumulative time of the cleaning solution. Therefore, even if the composition of the cleaning solution varies with a change in cumulative time, the etch amount of the target film is fixed with reliability.

Unlike the conventional examples, there is no need of replacing the cleaning solution flowing through the circulation line every time after a certain period has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 11

Hereinafter, an explanation of a cleaning apparatus for electronic devices according to Embodiment 11 of the present invention is provided.

The cleaning apparatus of Embodiment 11 is composed of the single-wafer cleaning apparatus of the first conventional example and a control unit 60 added thereto like the cleaning apparatus of Embodiment 7. Or alternatively, the cleaning apparatus of Embodiment 11 is composed of the single-wafer cleaning apparatus of the first conventional example and a CIM system 80 is connected thereto via the control unit 60 like the cleaning apparatus of Embodiment 7.

Therefore, in this embodiment, an explanation of the details of the cleaning apparatus already described in Embodiments 7 and 8 is omitted.

The control unit or the CIM system of the cleaning apparatus of Embodiment 11 determines etching temperature corresponding to the cumulative time instead of the etch time corresponding to the cumulative time.

Hereinafter, a detailed description of a method for determining the etching temperature corresponding to the cumulative time in the cleaning apparatus of Embodiment 11 is provided.

In order to determine a desired etching temperature, a polymer solution (containing 0.5% NH₄F, 45% organic solvent and 54.5% water) is fed into the circulation line as the cleaning solution. The temperature of the polymer solution is controlled by the electronic thermoregulator provided on the circulation line.

Under the above-described conditions, the polymer solution controlled to a certain etching temperature (25° C.) by the electronic thermoregulator is fed from the cleaning solution nozzle onto the target substrate supported on and being rotated by the holder for different etch times (3, 4, 5 and 6 minutes) to etch a target film (plasma TEOS film) on the. target substrate.

By measuring the etch amounts of the plasma TEOS film corresponding to different cumulative times, correlation between cumulative time and etch amount found when the etch time is varied (3, 4, 5 and 6 minutes) is evaluated. Hereinafter, referring to Table 13, the correlation between etching temperature and etch amount is explained.

Table 13 shows the etch amounts of the target film corresponding to the cumulative times (0 and 900 minutes) and the etch times (3, 4, 5 and 6 minutes).

As shown in Table 13, where the etch time is fixed (e.g., 5 minutes), 0.48 nm of the plasma TEOS film is etched when the cumulative time of the polymer solution is 0 minute. On the other hand, 0.96 nm of the plasma TEOS film is etched when the cumulative time of the polymer solution is 900 minutes.

TABLE 13

Cumulative time

| | 0 min | 900 min |
|---|---|---|
| Etch time (min) | Etch amount (nm) | Etch amount (nm) |
| 3 | 0.30 | 0.60 |
| 4 | 0.39 | 0.78 |
| 5 | 0.48 | 0.96 |
| 6 | 0.57 | 1.14 |

Next, under the above-described conditions, the polymer solution is fed from the cleaning solution nozzle onto the target substrate which is supported on and being rotated by the holder for certain etch time (5 minutes) to etch the target film (plasma TEOS film) on the target substrate.

By measuring the etch amounts of the plasma TEOS film corresponding to different etching temperatures, correlation between etching temperature and etch amount found when the cumulative time of the polymer solution is varied (0 and 900 minutes) is evaluated. Hereinafter, referring to Table 14, the correlation between etching temperature and etch amount is explained.

Table 14 shows the etch amounts of the target film corresponding to the etching temperatures measured when the cumulative time of the polymer solution is varied (0 minute and 900 minutes).

It is generally known that the etch amount of the target film depends on the etching temperature and represented by the Arrhenius' equation.

Therefore, as shown in Table 14, the etch amount of the plasma TEOS film increases at a certain rate with an increase in etching temperature whether the cumulative time is 0 minute or 900 minutes.

TABLE 14

Cumulative time

| Etching | 0 min | 900 min |
|---|---|---|
| temperature (° C.) | Etch amount (nm) | Etch amount (nm) |
| 15.0 | 0.21 | 0.43 |
| 16.5 | 0.24 | 0.48 |
| 20.0 | 0.33 | 0.66 |
| 25.0 | 0.48 | 0.96 |

For example, when the cumulative time of the polymer solution is 900 minutes, the etch amount of the plasma TEOS film increases (from 0.43, 0.48, 0.66 to 0.96 nm) with an increase in etching temperature (from 15.0, 16.5, 20.0 to 25.0° C.). Thus, the etch amount of the plasma TEOS film increases at a certain rate with an increase in etching temperature.

Therefore, when the cumulative time of the polymer solution is 900 minutes, the temperature of the polymer solution is adjusted from 25° C. to 16.5° C. such that the etch amount of the plasma TEOS film is surely fixed to 0.48 nm.

In order to adjust the etching temperature as described above, the cleaning apparatus of Embodiment 11 is provided with the control unit or the CIM system which determines suitable etching temperature corresponding to the cumulative time of the cleaning solution used.

For example, the control unit or the CIM system determines the etching temperature of 25° C. when the cumulative time of the polymer solution is 0 minute, or the etching temperature of 16.5° C. when the cumulative time of the polymer solution is 900 minutes.

As shown in FIGS. 16A, 16B, 18A and 18B, while the target substrate in the cleaning chamber is being rotated by the holder, the polymer solution is fed onto the target substrate for certain etch time under the etching temperature determined by the control unit or the CIM system, thereby etching the target film on the target substrate.

As described above, the cleaning apparatus of Embodiment 11 of the present invention is provided with the control unit or the CIM system which determines the etching temperature corresponding to the cumulative time of the cleaning solution. Further, in the cleaning chamber of the cleaning apparatus of Embodiment 11, the target film is etched at the desired etching temperature determined by the control unit or the CIM system for certain etch time.

Therefore, even if the composition of the cleaning solution varies with a change in cumulative time, the etch rate of the target film is not changed. Since the etching temperature is controlled by the control unit or the CIM system based on the cumulative time of the cleaning solution, the target film is etched under the suitable etching condition corresponding to the cumulative time. This prevents the etch amount of the target film from varying with the change in cumulative time. Therefore, the etch amount of the target film is fixed with reliability regardless of the cumulative time.

Further, unlike the conventional examples, there is no need of replacing the cleaning solution flowing through the circulation line every time after a certain period has elapsed since the cleaning solution was fed into the circulation line. That is, replacement of the cleaning solution is carried out less frequently. As a result, the quantity of the cleaning solution used is reduced and the operating rate of the cleaning apparatus improves, thereby leading to reduction in cost of manufacturing electronic devices.

### EMBODIMENT 12

Hereinafter, an explanation of a cleaning apparatus for electronic devices according to Embodiment 12 of the present invention is provided.

The cleaning apparatus of Embodiment 12 is composed of the single-wafer cleaning apparatus of the first conventional example and a control unit 60 added thereto like the cleaning apparatus of Embodiment 7. Or alternatively, the cleaning apparatus of Embodiment 12 is composed of the single-wafer cleaning apparatus of the first conventional example and a CIM system 80 is connected thereto via the control unit 60 like the cleaning apparatus of Embodiment 7.

Therefore, in this embodiment, an explanation of the details of the cleaning apparatus already described in Embodiments 7 and 8 is omitted.

The control unit or the CIM system of the cleaning apparatus of Embodiment 12 determines etching temperature corresponding to the cumulative time instead of the etch time corresponding to the cumulative time.

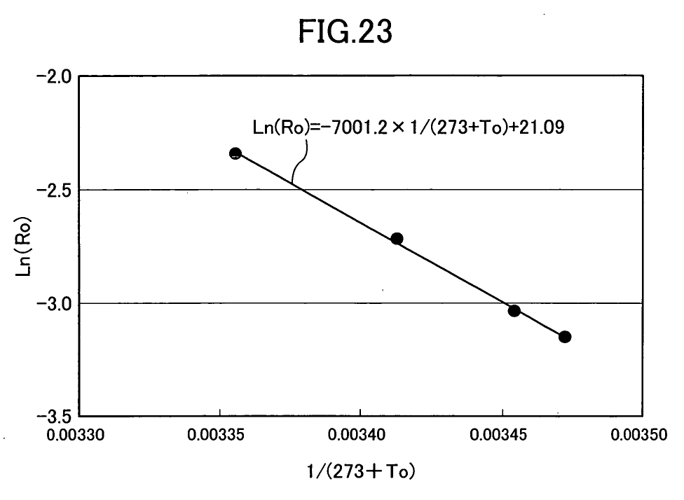

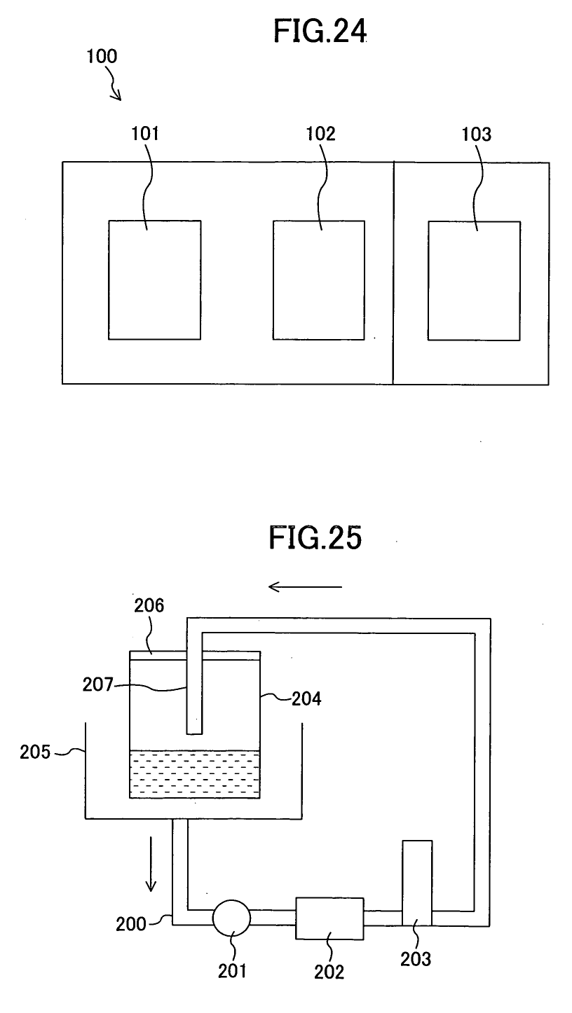

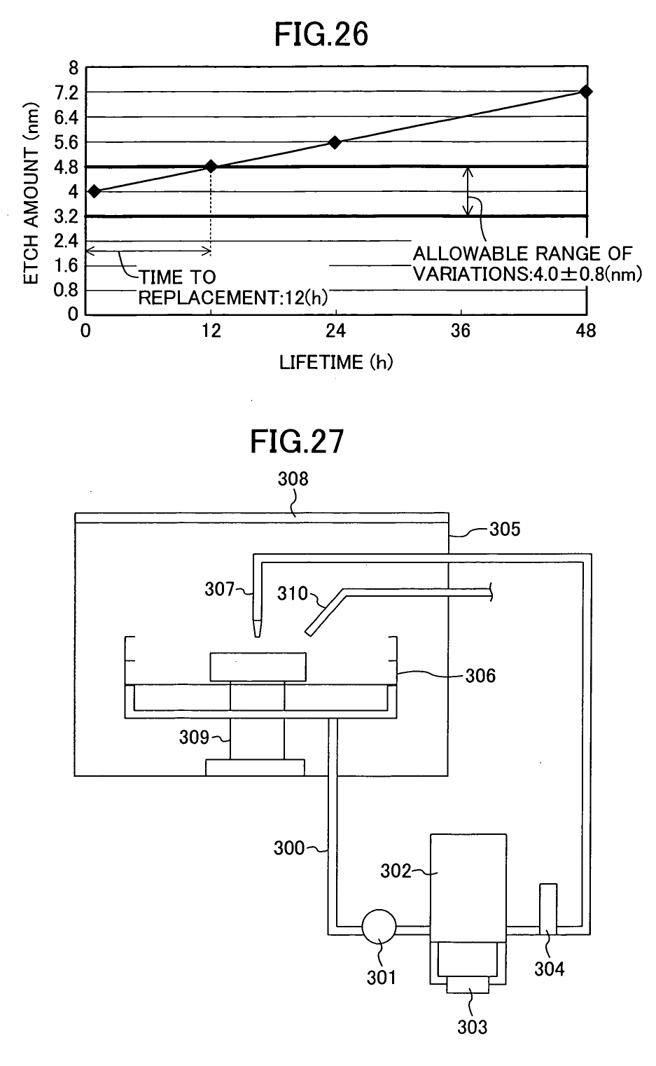

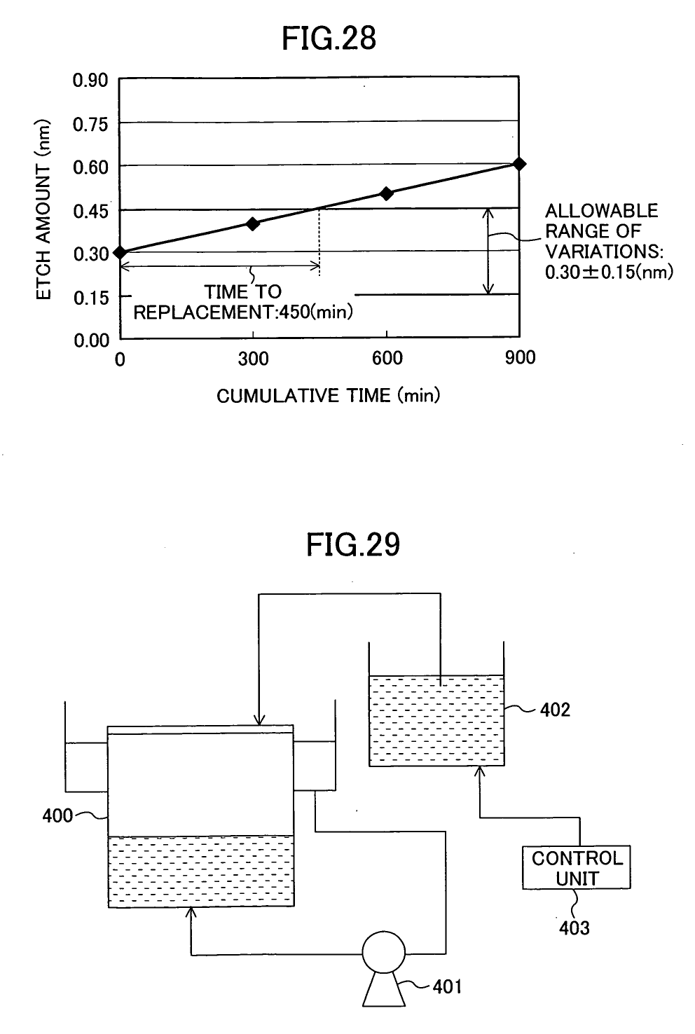

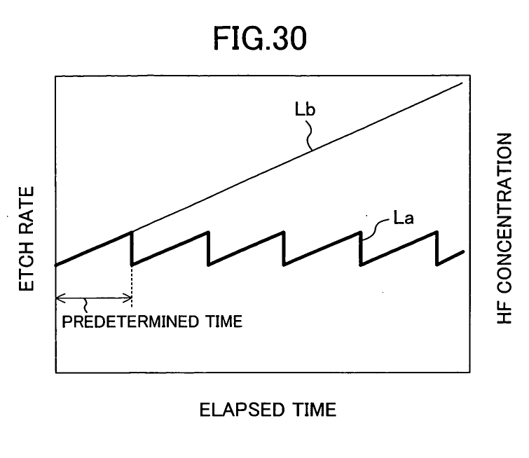

Hereinafter, with reference Table 15 and FIG. 23, an explanation of a correction formula for determining the etching temperature corresponding to the cumulative time of the cleaning solution in the cleaning apparatus of Embodiment 12 is provided.

Table 15 shows the etch rates of the target film corresponding to different etch times when the cleaning apparatus of Embodiment 12 is used and the cumulative time is 0 minute.

FIG. 23 is a graph illustrating correlation between 1/(273+To) and Ln(Ro) found when the cleaning apparatus of Embodiment 12 is used.

In this embodiment, the same explanation of the correction formula as described in Embodiment 9 is omitted.

In order to derive the correction formula for the cleaning apparatus of this embodiment, a polymer solution (containing 0.5% NH₄F, 45% organic solvent and 54.5% water) whose temperature (etching temperature) is controlled by the electronic thermoregulator is fed from the cleaning solution nozzle onto the target substrate which is supported on and being rotated by the holder for certain etch time, thereby etching a target film (plasma TEOS film) on the target substrate.

First, under the above-described conditions, an increase coefficient (F) of the etch rate of the thermal oxide film is obtained.

As described above, the increase coefficient (F) of the etch rate of the plasma TEOS film is determined from the approximate equation [e]. The etch rate at which the polymer solution etches the plasma TEOS film increases by 0.0001 (nm) per cumulative time (min).
Increase coefficient (F)=0.0001 (nm/min²)

Then, under the above-described conditions, the etch rate (E) of the plasma TEOS film when the cumulative time is 0 minute is obtained.

As described above, the etch rate (E) of the plasma TEOS film is obtained from the approximate equation [f]. The amount of the plasma TEOS film etched by the polymer solution just fed into the circulation line (cumulative time is 0 minute) increases by 0.09 (nm) per etch time (min).
Etch rate (E)=0.09 (nm/min)

Where the increase coefficient (F) and the etch rate (E) are thus obtained and the rate at which the plasma TEOS film is etched by the polymer solution when the cumulative time is Xn (min) is defined as Yn (nm/min), the etch rate Yn of the plasma TEOS film is obtained from the following formula [n].
Yn=0.0001Xn+0.09 [n]

Since the composition of the polymer solution varies with an increase in cumulative time, the etch rate Yn (nm/min) of the plasma TEOS film also increases with an increase in cumulative time Xn (min).

Then, as shown in Table 15, the etch rate Ro of the plasma TEOS film etched by the polymer solution which has spent 0-minute cumulative time is measured while varying the etching temperature To (15, 16.5, 20.0 and 25.0° C.). In this way, correlation between the etching temperature To and the etch rate Ro is evaluated.

TABLE 15

| Etching temperature | | Etch rate Ro | |
|---|---|---|---|
| To (° C.) | 1/(273 + To) | (nm/min) | Ln (Ro) |
| 15.0 | 0.0035 | 0.04 | −3.15 |
| 16.5 | 0.0035 | 0.05 | −3.04 |
| 20.0 | 0.0034 | 0.07 | −2.72 |
| 25.0 | 0.0034 | 0.10 | −2.34 |

As described above, it is generally known that the relationship between reaction rate and reaction temperature for a chemical reaction is expressed by the Arrhenius' equation. Since the etch rate Ro is a reaction rate for an etching reaction, the relationship between the etch rate Ro and the etching temperature To (reaction temperature) is represented by the following formula [o] based on the Arrhenius' equation.
Ln(Ro)=−Ea/R×1/(273+To)+InA [o]

In the formula [o], R is a gas constant and Ea and A are eigenvalues. Specifically, Ea represents free energy of activation and A is a frequency factor.

Next, in order to obtain the eigenvalues Ea and A of the formula [o], the etch rates Ro corresponding to the etching temperatures To are substituted into the formula [o].

Specifically, the Ln(Ro) values corresponding to 1/(273+To) indicated in Table 15 are plotted as shown in FIG. 23 to obtain the eigenvalues Ea and A.

Then, specific values of R, Ea and A are substituted into the formula [o] to obtain the following formula [p].
Ln(Ro)=−7001.2×1/(273+To)+21.09 [p]

From the formula [p], the etch rate Ro is obtained by the formula [q].
Ro=e^{t} [q]
(wherein t=−7001.2×1/(273+To)+21.09)

Since the composition of the cleaning solution varies with an increase in cumulative time as represented by the formula [n], the etch rate of the target film also increases.

Therefore, in order to fix the etch rate (0.09 nm/min) regardless of the cumulative time, it is necessary to determine the etching temperature based on the variations in etch rate corresponding to the variations in cumulative time. Thus, the following formula [r] is derived.
Etch rate (E)×[Etch rate (E)/Etch rate Yn]=Etch rate Ro=e^{t} [r]
(wherein t=−7001.2×1/(273+To)+21.09)

By obtaining the etching temperature To (° C.) from the formula [r], the following formula [4] is derived. From the formula [4], the etching temperature corresponding to the cumulative time Xn (min) is obtained.
Etching temperature To=7001.2/{21.09−Ln[Etch rate (E)×(Etch rate (E)/Etch rate Yn)]}−273 [4]

In this formula, the etch rate (E) is a value indicating the rate at which the amount of the target film etched by the cleaning solution just fed into the circulation line (cleaning solution circulation line) increases with an increase in etch time. For example, the etch rate (E) may be 0.09 (nm/min).

The etch rate Yn (nm/min) is a value indicating the rate at which the target film is etched by the cleaning solution for time Xn (min) elapsed since the cleaning solution was fed into the circulation line (cleaning solution circulation path).

For example, using the formula [4], the etching temperature To (° C.) corresponding to the cumulative time Xn (min) under the above-described conditions may be obtained by the following formula [40].
To=7001.2/{21.09−Ln[0.0081/(0.09+0.0001Xn)]}−273 [40]

From the formula [40], the etching temperature of 25° C. is determined when the cumulative time of the polymer solution is 0 minute, while 16.5° C. is determined when the cumulative time of the polymer solution is 900 minutes.

In the control unit or the CIM system of the cleaning apparatus of Embodiment 12, the formula [4] is set as a correction formula and the suitable etching temperature corresponding to the cumulative time is determined based on the formula [4].

For example, using the formula [4], the control unit or the CIM system of the cleaning apparatus of Embodiment 12 determines the etching temperature of 25° C. when the cumulative time of the polymer solution is 0 minute, or the etching temperature of 16.5° C. when the cumulative time of the polymer solution is 900 minutes.

As described above, the control unit or the CIM system of the cleaning apparatus of Embodiment 12 determines the suitable etching temperature corresponding to the cumulative time using the formula [4] as shown in FIG. 16A or 16B and FIG. 18A or 18B. Then, in the cleaning chamber of the cleaning apparatus of this embodiment, the target film is etched at the desired etching temperature determined by the control unit or the CIM system for certain etch time.

Therefore, even if the composition of the cleaning solution varies with a change in cumulative time, the etch rate of the target film is not changed. Since the control unit or the CIM system determines the etching temperature based on the cumulative time of the cleaning solution, the target film is etched under the suitable etching condition corresponding to the cumulative time. That is, the etch amount of the target film is prevented from varying with the change in cumulative time. Therefore, the etch amount of the target film is fixed with reliability regardless of the cumulative time.

Further, unlike the conventional examples, there is no need of replacing the cleaning solution flowing through the circulation line every time after a certain period has elapsed since the cleaning solution was fed into the circulation line. Therefore, replacement of the cleaning solution is carried out less frequently. As a result, the quantity of the cleaning solution used is reduced and the operating rate of the cleaning apparatus improves, thereby leading to reduction in cost of manufacturing electronic devices.

According to the apparatus and method for cleaning electronic devices described in Embodiments 1-4 and 7-10, the control unit or the CIM system determines certain etch time corresponding to elapsed time, and then a target film is etched for the determined etch time at a certain etching temperature. However, in addition to the etch time, the etching temperature may also be determined based on the elapsed time so that the target film is etched for the etch time and at the etching temperature both corresponding to the elapsed time.

According to the apparatus and method for cleaning electronic devices described in Embodiments 5, 6, 11 and 12, the control unit or the CIM system determines suitable etching temperature corresponding to elapsed time, and then a target film is etched at the determined etching temperature for certain etch time. However, in addition to the etching temperature, the etch time may also be determined based on the elapsed time so that the target film is etched at the etching temperature and for the etch time both corresponding to the elapsed time.

Thus, the present invention is useful for an apparatus and a method for cleaning electronic devices.

What is claimed is:

1. A method for cleaning electronic devices including the step of etching a target substrate placed in a cleaning chamber using a cleaning solution which is circulated for reuse in a cleaning solution circulation path including at least the cleaning chamber and a cleaning solution circulation line, the method further comprising the steps of:
(a) determining etch time based on data concerning variations in amount of a target film on the target substrate etched by the cleaning solution, the variations depending on time elapsed since the cleaning solution was fed into the cleaning solution circulation path;
(b) etching the target substrate in the cleaning chamber using the cleaning solution for the determined etch time; and
(c) rinsing the target substrate with water.

2. A method according to claim 1, wherein
the etch time is determined based on data concerning variations in amount of the target film etched in the step (c) by the remainder of the cleaning solution used in the step (b).

3. A method according to claim 1, wherein
the etch time is determined based on data concerning variations in etch amount of the target film that depend on time elapsed since the cleaning solution was fed into the cleaning solution circulation path until the cleaning solution is discharged from the cleaning solution circulation path.

4. A method according to claim 3, wherein
the etch time is determined by the formula [1]:
Etch time={Intended etch amount−[Additional etch amount (C)+Additional etch rate (D)×Lifetime]}/{Etch rate (A)+Increase coefficient (B)×Lifetime}
wherein
the lifetime indicates time elapsed since the cleaning solution was fed into the cleaning solution circulation path,
the increase coefficient (B) is a value indicating the rate at which the etch rate of the target film increases with an increase in lifetime,
the etch rate (A) is a value indicating the rate at which the amount of the target film etched in the step (b) by the cleaning solution which has just fed into the cleaning solution circulation path increases with an increase in etch time,
the additional etch amount (C) is a value indicating the amount of the target film additionally etched in the step (c) by the remainder of the cleaning solution which has just fed into the cleaning solution circulation path and
the additional etch rate (D) is a value indicating the rate at which the additional etch amount increases with an increase in lifetime.

5. A method according to claim 1, wherein
the cleaning chamber is adapted to a single-wafer cleaning apparatus and
the etch time is determined based on data concerning variations in etch amount of the target film that depend on cumulative time spent for etching the target substrate since the cleaning solution was fed into the cleaning solution circulation path.

6. A method according to claim 5, wherein
the etch time is determined by the formula [2]:
Etch time={Intended etch amount−[Additional etch amount (G)+Additional etch rate (H)×Cumulative time]}/{Etch rate (E)+Increase coefficient (F)×Cumulative time}
wherein
the cumulative time is a value indicating the sum of durations spent for etching the target substrate since the cleaning solution was fed into the cleaning solution circulation path,
the increase coefficient (F) is a value indicating the rate at which the etch rate of the target film increases with an increase in cumulative time,
the etch rate (E) is a value indicating the rate at which the amount of the target film etched in the step (b) by the cleaning solution which has just fed into the cleaning solution circulation path increases with an increase in etch time,
the additional etch amount (G) is a value indicating the amount of the target film additionally etched in the step (c) by the remainder of the cleaning solution which has just fed into the cleaning solution circulation path and
the additional etch rate (H) is a value indicating a rate at which the additional etch amount increases with an increase in cumulative time.

7. A method according to claim 1, wherein the cleaning solution contains a fluorine compound.

8. A method for cleaning electronic devices including the step of etching a target substrate placed in a cleaning chamber using a cleaning solution which is circulated for reuse in a cleaning solution circulation path including at least the cleaning chamber and a cleaning solution circulation line, the method further comprising the steps of:
(d) determining etching temperature based on data concerning variations in amount of a target film on the target substrate etched by the cleaning solution, the variations depending on time elapsed since the cleaning solution was fed into the cleaning solution circulation path;
(e) etching the target substrate in the cleaning chamber using the cleaning solution controlled at the determined etching temperature; and
(f) rinsing the target substrate with water.

9. A method according to claim 8, wherein
the etching temperature is determined based on data concerning variations in etch amount of the target film that depend on time elapsed since the cleaning solution was fed into the cleaning solution circulation path until the cleaning solution is discharged from the cleaning solution circulation path.

10. A method according to claim 8, wherein
the cleaning chamber is adapted to a single-wafer cleaning apparatus and
the etching temperature is determined based on data concerning variations in etch amount of the target film that depend on cumulative time spent for etching the target substrate since the cleaning solution was fed into the cleaning solution circulation path.

11. A method according to claim 8, wherein the cleaning solution contains a fluorine compound.

12. A cleaning apparatus for electronic devices comprising:
a cleaning solution circulation path which circulates a cleaning solution therein for reuse and includes a cleaning solution circulation line which is provided with a temperature regulator mechanism for controlling the temperature of the cleaning solution and a cleaning chamber in which the target substrate is cleaned; and
a control unit for measuring time elapsed since the cleaning solution was fed into the cleaning solution circulation path and determining etch time based on data concerning variations in amount of a target film on the target substrate etched by the cleaning solution, the variations depending on the elapsed time, wherein
the target substrate is etched in the cleaning chamber using the cleaning solution for the etch time determined by the control unit.

13. A cleaning apparatus according to claim 12, wherein
the control unit selects a desired etch time from a plurality of previously set etch times depending on the determined etch time or
changes a previously selected etch time to a desired etch time depending on the determined etch time.

14. A cleaning apparatus according to claim 12, wherein
the control unit determines the etch time based on data concerning variations in amount of the target film etched by the remainder of the cleaning solution.

15. A cleaning apparatus according to claim 12, wherein
the etch time is determined based on data concerning variations in etch amount of the target film that depend on time elapsed since the cleaning solution was fed into the cleaning solution circulation path until the cleaning solution is discharged from the cleaning solution circulation path.

16. A cleaning apparatus according to claim 12, wherein
the cleaning chamber includes therein
a holder which supports the target substrate rotatably and
a nozzle which communicates with the cleaning solution circulation line and through which the cleaning solution is fed onto the target substrate, and
the etch time is determined based on data concerning variations in etch amount of the target film that depend on cumulative time spent for etching the target substrate since the cleaning solution was fed into the cleaning solution circulation path.

17. A cleaning apparatus for electronic devices comprising:
a cleaning solution circulation path which circulates a cleaning solution therein for reuse and includes a cleaning solution circulation line which is provided with a temperature regulator mechanism for controlling the temperature of the cleaning solution and a cleaning chamber in which the target substrate is cleaned; and
a control unit for measuring time elapsed since the cleaning solution was fed into the cleaning solution circulation path and determining etching temperature based on the amount of a target film on the target substrate etched by the cleaning solution, the amount varying depending on the elapsed time, wherein
the target substrate is etched in the cleaning chamber using the cleaning solution controlled at the etching temperature determined by the control unit.

18. A cleaning apparatus according to claim 17, wherein
the control unit sends data of the determined etching temperature to the temperature regulator mechanism.

19. A cleaning apparatus according to claim 17, wherein
the etching temperature is determined based on data concerning variations in etch amount of the target film that depend on time elapsed since the cleaning solution was fed into the cleaning solution circulation path until the cleaning solution is discharged from the cleaning solution circulation path.

20. A cleaning apparatus according to claim 17, wherein
the cleaning chamber includes therein
a holder which supports the target substrate rotatably and
a nozzle which communicates with the cleaning solution circulation line and through which the cleaning solution is fed onto the target substrate, and
the etching temperature is determined based on data concerning variations in etch amount of the target film that depend on cumulative time spent for etching the target substrate since the cleaning solution was fed into the cleaning solution circulation path.
